(19) United States
(12) Patent Application Publication
(10) Pub. No.: US 2015/0241794 A1
(43) Pub. Date: Aug. 27, 2015

(54) Coil Switching Method for Moving Magnet Planar Motor

(71) Applicant: Nikon Corporation, Tokyo (JP)

(72) Inventors: Pai-Hsueh Yang, Palo Alto, CA (US); J. Kyle Wells, San Bruno, CA (US); Michael B. Binnard, Belmont, CA (US); Tsutomu Ogiwara, Tokyo (JP); Shigeru Morimoto, Saitama (JP); Kazuhiro Hirano, Saitama (JP)

(21) Appl. No.: 14/529,904

(22) Filed: Oct. 31, 2014

Related U.S. Application Data
(60) Provisional application No. 61/897,925, filed on Oct. 31, 2013.

(51) Int. Cl. G03F 7/20; H02P 25/02; H02K 41/03

(52) U.S. Cl. CPC G03F 7/70758; H02K 41/031; H02P 25/028

(57) ABSTRACT

According to one aspect, an apparatus includes a stage, a motor to move the stage, an amplifier, and a controller. The motor has at least a first coil and a second coil, and the amplifier is configured to selectively provide current to either the first coil or the second coil. The controller is configured to control force generated by the motor. When moving the stage, the controller controls the motor force by using the amplifier to provide current to the first coil, smoothly reducing a force generated by the first coil before the stage moves to a predetermined switching location so that the coil is generating substantially no force at the switching location, switching the amplifier so that the amplifier provides current to the second coil, and smoothly increasing a force generated by the second coil after the stage moves past the predetermined switching location.

### CROSS-REFERENCE TO RELATED APPLICATION

The present application claims benefit under 35 U.S.C. §119(e) of U.S. Provisional Patent Application No. 61/897,925, entitled “Smooth Coil Switching Method for Moving Magnet Planar Motor,” filed Oct. 31, 2013, which is incorporated herein by reference in its entirety for all purposes.

### BACKGROUND OF THE INVENTION

1. Field of the Invention

The present invention relates generally to equipment used in semiconductor processing. More particularly, the present invention relates to efficiently reducing the occurrence of force discontinuity of a planar motor during coil switching.

2. Description of the Related Art

Planar motors often include more than one coil. During the course of operating a planar motor, coil switching may occur in which the planar motor switches from using one coil to using another coil. During coil switching, force discontinuities generally occur. Such force discontinuities may adversely affect the operation of a planar motor and, when the planar motor is used to drive a stage, the accuracy with which the stage may scan. When the accuracy with which a stage may scan is adversely affected, the quality of a semiconductor formed using the stage may be compromised.

### SUMMARY OF THE INVENTION

According to one aspect of the present invention, a method for operating a planar motor that includes a magnet array having a first magnet unit, e.g., quadrant, with an associated range and a coil array including at least a first coil and a second coil includes providing electrical current to the first coil when the first coil is within the range, and determining when the first magnet unit is in proximity to a switching location. When it is determined that the first magnet unit is in proximity to the switching location, the electrical current provided to the first coil is reduced. After reducing the electrical current provided to the first coil, it is determined whether the first magnet unit has reached the switching location. The method also includes switching to providing the electrical current to a second coil when it is determined that the first magnet unit has reached the switching location, wherein switching to providing the electrical current to the second coil includes ceasing providing the electrical current to the first coil.

In accordance with another aspect of the present invention, an apparatus includes a stage, a motor to move the stage, an amplifier, and a controller. The motor has at least a first coil and a second coil, and the amplifier is configured to selectively provide electrical current to either the first coil or the second coil. The controller is configured to control force generated by the motor. When moving the stage, the controller controls the motor force by using the amplifier to provide electrical current to the first coil, smoothly reducing a force generated by the first coil before the stage moves to a predetermined switching location so that the coil is generating substantially no force when the stage is at the switching location, switching the amplifier so that the amplifier provides electrical current to the second coil, and smoothly increasing a force generated by the second coil after the stage moves past the predetermined switching location. Smoothly reducing the force generated by the first coil force, switching the amplifier output when the current is substantially zero, and smoothly increasing the force generated by the second coil reduces discontinuities in the force generated by the motor when moving the stage.

### BRIEF DESCRIPTION OF THE DRAWINGS

The invention will be readily understood by the following detailed description in conjunction with the accompanying drawings, in which:

FIG. 1A is a diagrammatic representation of a magnet array of a planar motor in accordance with an embodiment of the present invention.

FIG. 1B is a diagrammatic representation of a coil array of a planar motor in accordance with an embodiment of the present invention.

FIG. 2 is a diagrammatic representation of a moving magnet planar motor system which utilizes smooth coil switching in accordance with an embodiment of the present invention.

FIG. 3A-3D are diagrammatic representations of a process of turning on a substantially minimal number of coils, e.g., YZ coils, under a magnet quadrant, e.g., a YZ magnet quadrant, during a unit-by-unit coil switching event in a force direction in accordance with an embodiment of the present invention.

FIG. 3E-3H are a diagrammatic representation of a process of turning on extra coils under a magnet quadrant prior to a unit-by-unit coil switching event in a force direction in accordance with an embodiment of the present invention.

FIGS. 4A and 4B are a diagrammatic representation of a process of turning on a substantially minimal number of coils, e.g., YZ coils, under a magnet quadrant, e.g., a YZ magnet quadrant, during a unit-by-unit coil switching event in a cross direction in accordance with an embodiment of the present invention.

FIGS. 4C and 4D are a diagrammatic representation of a process of turning on extra coils under a magnet quadrant during a unit-by-unit coil switching event in a cross direction in accordance with an embodiment of the present invention.

FIG. 5A-5D are a diagrammatic representation of a process of turning on at least one coil outside of a magnet quadrant during a coil-by-coil coil switching event in a force direction in accordance with an embodiment of the present invention.

FIGS. 5E and 5F are a diagrammatic representation of a process of performing a coil-by-coil switch in a cross direction in accordance with an embodiment of the present invention.

FIGS. 6A-6D are a diagrammatic representation of a process of coil switching for two YZ magnet quadrants of a planar motor for movement in a force direction in accordance with an embodiment of the present invention.

FIGS. 6E and 6F are a diagrammatic representation of a process of coil switching for two YZ magnet quadrants of a planar motor for movement in a cross direction in accordance with an embodiment of the present invention.

FIGS. 6G and 6H are a diagrammatic representation of coil-by-coil coil switching for two YZ magnet quadrants of a planar motor for movement in a cross direction in accordance with an embodiment of the present invention.

FIG. 7A is a diagrammatic representation of a YZ coil and amplifier connection layout for a coil array in accordance with an embodiment of the present invention.

FIG. 7B is a diagrammatic representation of a XZ coil and amplifier connection layout for a coil array, e.g., coil array 750 of FIG. 7A, in accordance with an embodiment of the present invention.

FIG. 8A is a diagrammatic representation of a coil current scaling in a force direction in accordance with an embodiment of the present invention.

FIG. 8B is a diagrammatic representation of a coil current scaling in a cross direction in accordance with an embodiment of the present invention.

FIG. 9 is a diagrammatic representation of a coil current command in accordance with an embodiment of the present invention.

FIG. 10 is a process flow diagram which illustrates one method of switching coils in accordance with an embodiment of the present invention.

FIG. 11 is a diagrammatic representation of a photolithography apparatus in accordance with an embodiment of the present invention.

FIG. 12 is a process flow diagram which illustrates the steps associated with fabricating a semiconductor device in accordance with an embodiment of the present invention.

FIG. 13 is a process flow diagram which illustrates the steps associated with processing a wafer, i.e., step 1113 of FIG. 12, in accordance with an embodiment of the present invention.

### DETAILED DESCRIPTION OF THE INVENTION

Example embodiments of the present invention are discussed below with reference to the various figures. However, those skilled in the art will readily appreciate that the detailed description given herein with respect to these figures is for explanatory purposes, as the invention extends beyond these embodiments.

In order for a stage to be driven by a moving magnet planar motor with a substantially minimal number of amplifiers, the amplifiers may connect to different coils based on a position of the stage such that coil switching may be implemented. As will be appreciated by those skilled in the art, the magnet arrays of a planar motor may have a relatively noticeable edge effect, e.g., magnetic flux leakage of outside magnet arrays, which may cause force discontinuity during coil switching.

Within an overall stage apparatus, the problem of force discontinuity which occurs in a planar motor during coil switching is solved by utilizing two types of switching, e.g., unit-by-unit switching and coil-by-coil switching, depending on whether multi-phase, e.g., three-phase, amplifiers or single-phase amplifiers are used. That is, the type of switching used may depend on whether the amplifiers used substantially require balanced phase currents, where the sum of u, v, and w phase currents is substantially zero, or whether single-phase amplifiers which allow independent phase current control where u, v, and w phase currents may be independently controlled are used. Unit-by-unit switching generally involves switching units that each include multiple coils, while coil-by-coil switching generally involves switching coils individually. In one embodiment, unit-by-unit switching may be used with balanced three-phase amplifiers while coil-by-coil switching may be used with either independent three-phase amplifiers or single-phase amplifiers. When compared with unit-by-unit switching, coil-by-coil switching generally leads to better efficiency with fewer amplifier channels and less generated heat.

By utilizing a smooth scaling factor for coil current commands, a motor force discontinuity caused by coil switching may be substantially removed. That is, the application of a smooth coil current command scaling factor may allow for a substantially smooth transition between coils used to generate motor force. The same formulation may generally be applied to both X and Y directions which are parallel or perpendicular to a motor force direction. Utilizing a relatively simple and substantially deterministic formulation for coil switching may improve motor efficiency, utilize fewer amplifiers, and generate less heat.

A smooth transition between coils, or a smooth coil switch, is generally a switch from one coil to another coil while substantially maintaining continuity of both a function that specifies coil currents and the derivative of that function such that stage vibrations during the coil switch may be significantly reduced. During a smooth coil switch, the electrical switching event from one coil to another coil occurs when a current command is substantially zero. In other words, a coil switch is generally a switch from one coil to another coil which is made when a current command to both of the coils is substantially zero, and the current command is adjusted according to a continuous and differentiable function before and after the switch.

In one embodiment, a motor or actuator includes more than two coils such that when a stage is moving, the relative position of the coils and at least one associated motor magnet array is such that some coils are temporarily not used, e.g., temporarily not connected to amplifiers, while other coils may be switching their amplifier connections and still other coils may generate a relatively steady force. A controller may determine current commands of amplifiers which are connected to the coils switching their amplifier connections and to the coils generating force. Amplifier current commands for coils may be manipulated or controlled to generate a relatively smooth force, or a force without significant disturbances, during switching.

Generally, a motor force command may be transformed to amplifier current commands through a motor commutation formula. In one embodiment, a motor commutation formula may include a set of sinusoidal functions of relative positions between a magnet array and coils, as for example with magnitude being proportional to a motor force command.

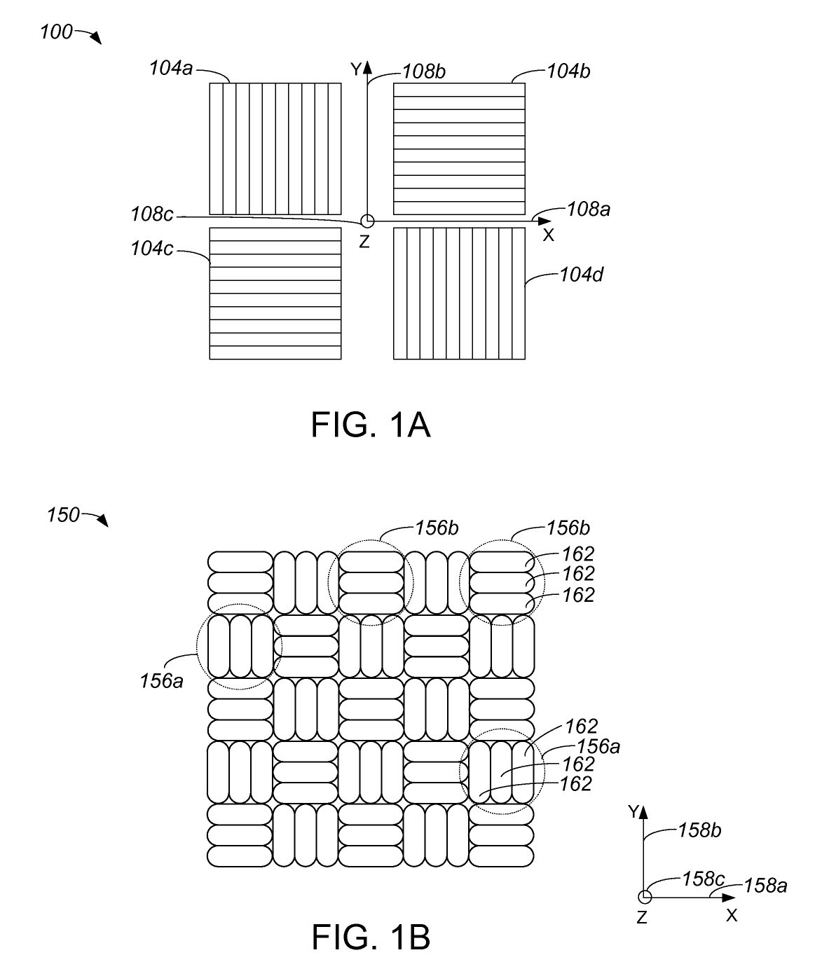

FIG. 1A is a diagrammatic representation of a magnet array of a planar motor in accordance with an embodiment of the present invention. The magnet array 100 of a planar motor, as shown, contains four sections 104a-d, e.g., quadrants, of a magnet assembly. Quadrants 104a, 104c are generally used to generate force along an X axis 108a and a Z axis 108c, while quadrants 104b, 104d are generally used to generate force along a Y axis 108b and Z axis 108c. It should be appreciated that spacing between quadrants 104a-d may vary widely. For example, spacing between adjacent quadrants 104a-d along X axis 108a may be approximately 150 millimeters (mm) while spacing between adjacent quadrants 104a-d along Y axis 108b may be a few millimeters or less. It should be appreciated that the use of the term “quadrant” is not intended to limit magnet array 100 to including four sections, and generally refers to a set section of magnets. In some embodiments, magnet array 100 may include more than four or fewer than four sections or quadrants. By way of example, a magnet array may include a single sub-array, or a single quadrant.

FIG. 1B is a diagrammatic representation of a coil array of a planar motor, as for example the same planar motor which includes magnet array 100 of FIG. 1A, in accordance with an embodiment of the present invention. A coil array 150 contains XZ coil units 156a and YZ coil units 156b. XZ coil units 156a are configured to generate force in an X axis 158a and a Z axis 158c, while coil units 156b are configured to generate force in a Y axis 158b and Z axis 158c. Coil units 156a, 156b may be arranged in a checkerboard pattern, and/or in two substantially separate layers. In one embodiment, each coil unit 156a, 156b may include three coils 162 of u, v, and w phases. In alternate embodiments, each coil unit 156a, 156b may include more than three coils, e.g., six coils or nine coils, and may be considered as three electrical phases u, v, and w.

A single XZ or YZ coil under a magnet array, as for example a magnet array as shown in FIG. 1A, may generate substantially sinusoidal X and Z forces, and/or Y and Z forces, respectively. A flux may be generated by a magnet quadrant, and effectively extend beyond a boundary of the magnet quadrant in a X direction and/or a Y direction. To reduce an edge effect, e.g., a force ripple, due to this flux, and to maintain force uniformity through different positions with respect to a X direction and/or a Y direction, one or more coils which are substantially outside of the magnet quadrant, e.g., do not lie substantially under the magnet quadrant relative to a Z direction, may be energized. In one embodiment, a smoothing algorithm may be used to maintain motor force continuity during coil switching.

For a coil unit to generate substantially constant X and Z forces, or substantially constant Y and Z forces, three-phase coil current commutation formulas may be applied to the appropriate current commands of the associated three-phase coils within the coil unit. It should be appreciated that any suitable three-phase commutation formula may be applied to current commands. A first suitable three-phase commutation formula for XZ coils is as follows:

$$( \begin{matrix}{I}_{u} \\ {I}_{v} \\ {I}_{w}\end{matrix} ) = ( \begin{matrix}sin ( θ + \frac{2 π}{3} ) & - cos ( θ + \frac{2 π}{3} ) \\ sin ( θ ) & - cos ( θ ) \\ sin ( θ - \frac{2 π}{3} ) & - cos ( θ - \frac{2 π}{3} )\end{matrix} ) \cdot ( \begin{matrix}{I}_{x} \\ {I}_{z}\end{matrix} ) θ = \frac{2 π ( - x + {x}_{o} )}{L}$$

A second suitable three-phase commutation formula for YZ coils is as follows:

$$( \begin{matrix}{I}_{u} \\ {I}_{v} \\ {I}_{w}\end{matrix} ) = ( \begin{matrix}sin ( θ + \frac{2 π}{3} ) & - cos ( θ + \frac{2 π}{3} ) \\ sin ( θ ) & - cos ( θ ) \\ sin ( θ - \frac{2 π}{3} ) & - cos ( θ - \frac{2 π}{3} )\end{matrix} ) \cdot ( \begin{matrix}{I}_{y} \\ {I}_{z}\end{matrix} ) θ = \frac{2 π ( - y + {y}_{o} )}{L}$$

The type of coil switching algorithm which is used with respect to motion of a magnet quadrant is dependent, at least in part, upon an amplifier configuration. By way of example, for three-phase amplifiers which utilize balanced currents, i.e., the sum of u, v, and w currents is substantially zero, a unit-by-unit coil switching algorithm may be applied. In alternate embodiments, a coil-by-coil switching algorithm may lead to better motor efficiency and generate less heat when the amplifiers are configured to have independent phase current control, i.e., when each of the u, v, and w currents may be independently controlled.

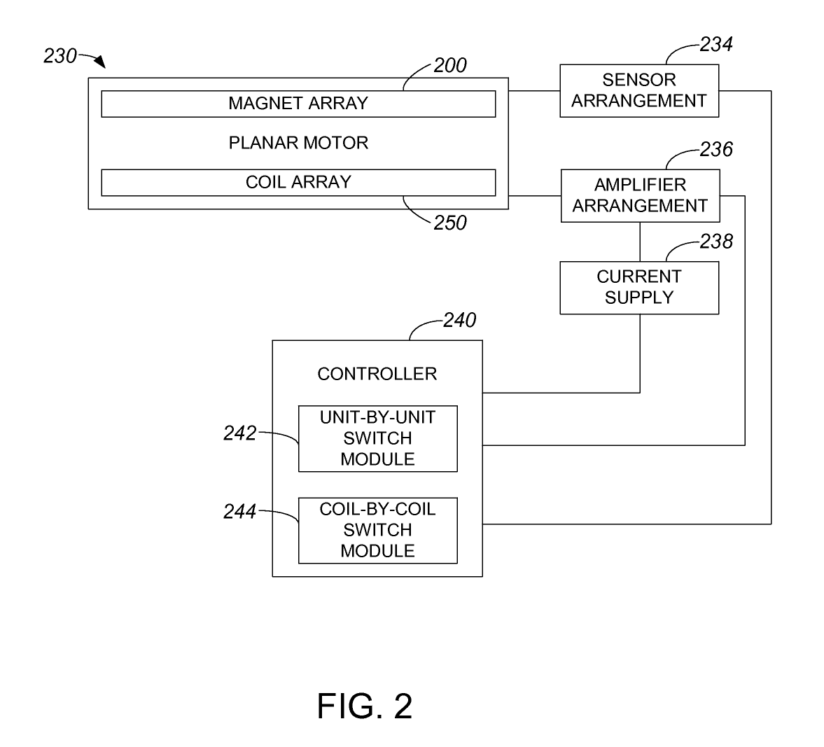

FIG. 2 is a diagrammatic representation of a moving magnet planar motor system in accordance with an embodiment. A moving magnet planar motor system includes a moving magnet planar motor which includes a magnet array 200 and a coil array 250. Magnet array 200 may generally include quadrants of magnets, while coil array 250 may generally include an array of coil units. A stage (not shown) may be coupled to moving magnet planar motor 230 such that moving magnet planar motor 230 allows the stage to move. It should be appreciated that such a stage may either be coupled to magnet array 200 or to coil array 250.

A sensor arrangement 234 includes any number of sensors or sensing devices, and may be configured to identify a location of a particular magnet quadrant of magnet array 200 with respect to particular coil units in coil array 250. In other words, sensor arrangement 234 may provide information relating to the positioning of magnet array 200 relative to coil array 250. Information from sensor arrangement 234 may be provided to a controller 240, which uses the information to control an amplifier arrangement 236 and a current supply 238 as appropriate. Controller 240 controls amplifier arrangement 246 and current supply 238 as needed to energize coils in coil array 250 efficiently.

Controller 240 includes unit-by-unit switch module 242 and coil-by-coil switch module 244. Modules 242, 244 may generally include hardware and/or software logic, e.g., software logic arranged to be executed by a processor (not shown) associated with controller 240. In general, module 242, 244 are each configured to apply a smooth scaling factor for coil current commands.

Unit-by-unit switch module 242 is configured to identify which coil units of coil array 250 are to be turned on or turned off, and to cause appropriate coil units to be turned on or turned off. Unit-by-unit switch module 242 is also generally arranged to cause amplifier arrangement 236 to smoothly reduce a force generated by a coil unit (not shown) of coil array 250 that is to be turned off, and to cause individual amplifiers (not shown) in amplifier arrangement 236 to switch from providing current from current supply 238 to one coil unit to providing current from current supply 238 to another coil unit. When switching to providing current from current supply 238 to another coil unit (not shown), unit-by-unit switch module 242 may control amplifiers 236 such that amplifiers 236 may smoothly increase the force generated by that coil unit. Smoothly increasing force and smoothly decreasing force may generally involve smoothly increasing current and smoothly decreasing current, respectively.

Coil-by-coil switch module 244 is configured to identify which individual coils of coil array 250 are to be turned on or turned off, and to cause appropriate individual coils to be turned on or turned off. Coil-by-coil switch module 244 is also generally arranged to cause amplifier arrangement 236 to smoothly reduce a force generated by a coil that is to be turned off, and to cause amplifiers (not shown) in amplifier arrangement 236 to switch from providing current from current supply 238 to one coil to providing current from current supply 238 to another coil. When switching to providing current from current supply 238 to another coil (not shown), coil-by-coil switch module 244 may control amplifiers 236 such that amplifiers 236 may smoothly increase the force generated by that coil.

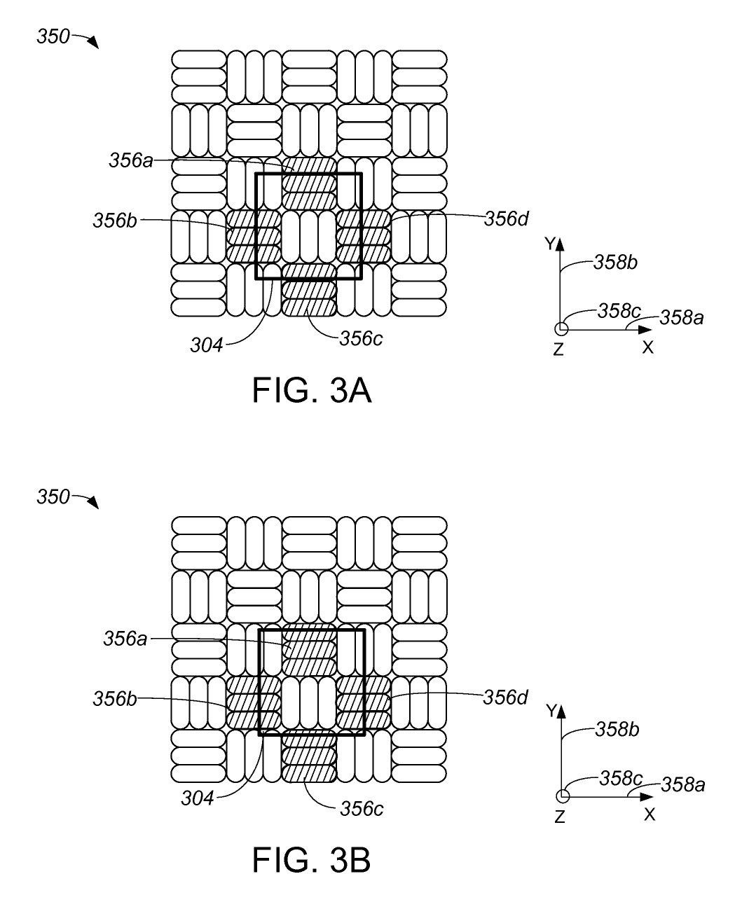

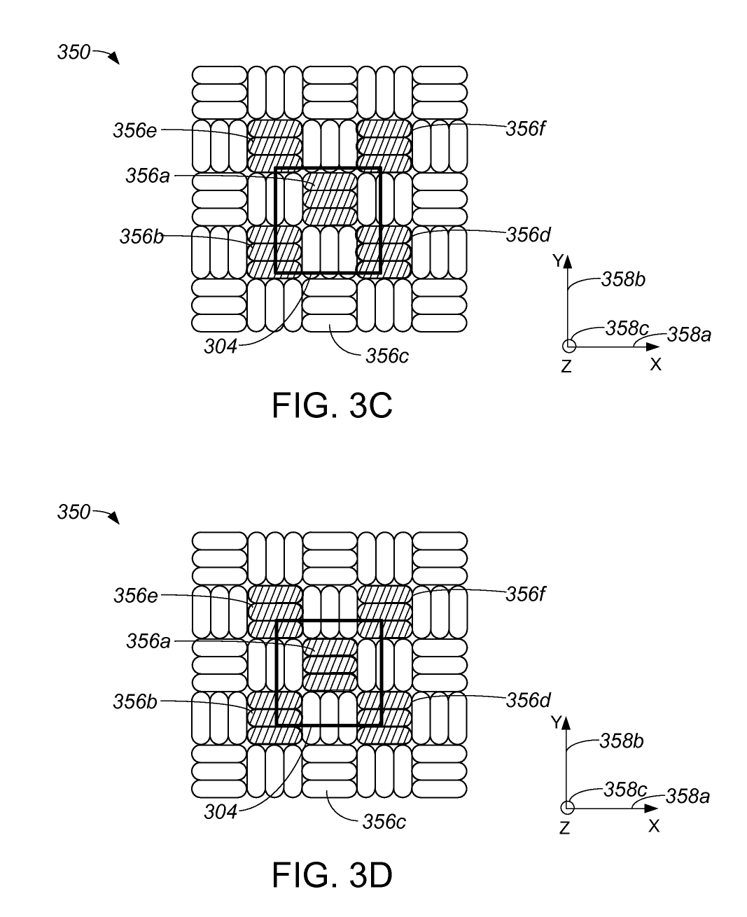

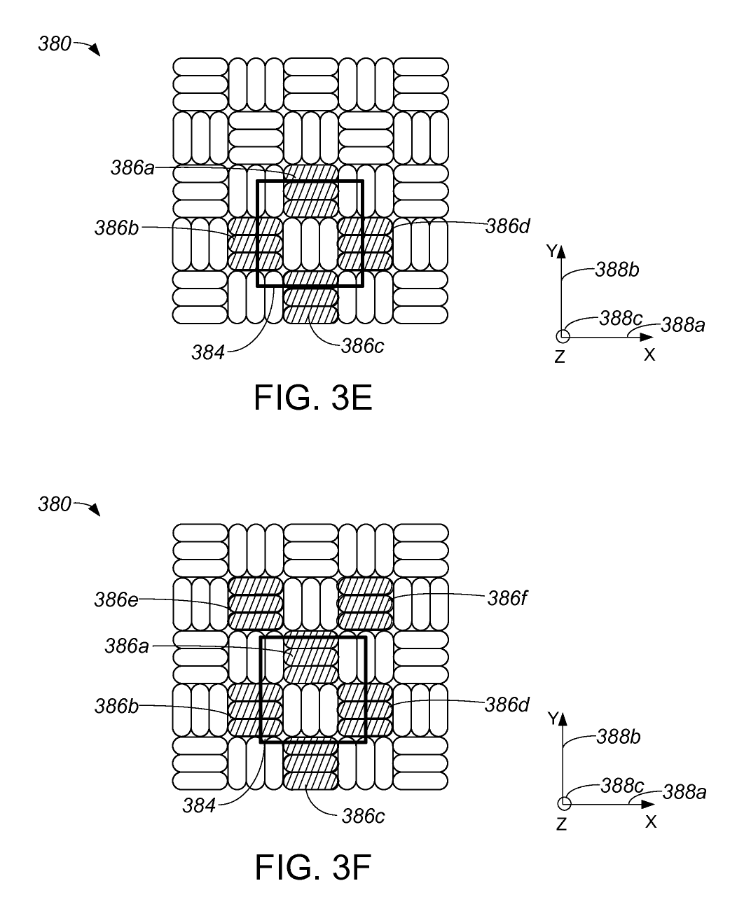

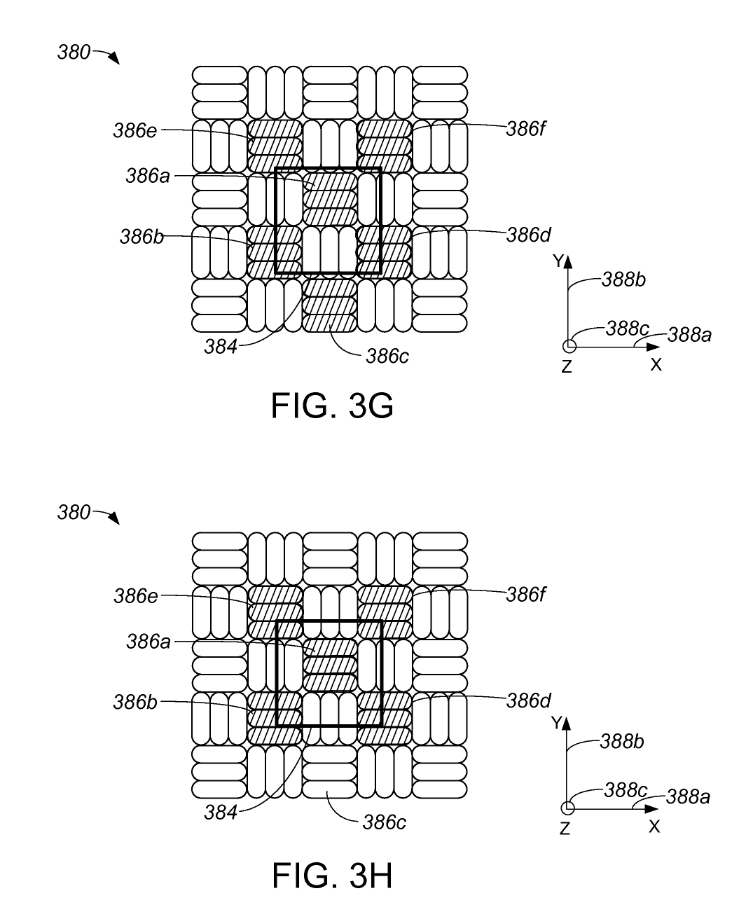

With reference to FIGS. 3A-3D, a process of turning on a substantially minimal number of coils, e.g., YZ coils, under a magnet quadrant, e.g., a YZ magnet quadrant, during a unit-by-unit coil switch in a force direction will be described in accordance with an embodiment of the present invention. For a given quadrant and/or coil unit, a “force direction” is defined as either the X or Y direction in which the quadrant and/or coil unit produces a substantial force. The perpendicular direction, i.e., a X or Y direction, is referred to herein as the “cross direction.” For the examples shown in FIGS. 3A-3D, for a YZ quadrant and coil units shown, the force direction is the Y direction and the cross direction is the X direction. As shown in FIG. 3A, at a time t1, four YZ coil units 356a-d of an overall coil array 350, which are located substantially under a YZ magnet quadrant 304, may initially be energized. It should be appreciated that each YZ coil unit 356a-d may generally include any number of YZ coils. Energized YZ coil units 356a-d are coils arranged to cooperate with YZ magnet quadrant 304 to create force along a Y axis 358b and along a Z axis 358c. YZ coil units 356a-d are located substantially under YZ magnet quadrant 304 relative to Z axis 358c. and are effectively within a range of YZ magnet quadrant 304. More generally, overall coil array 350 is located at a distance, preferably a relatively small distance, away from YZ magnet quadrant 304 relative to Z axis 358c. At a time t2, as shown in FIG. 3B, YZ coil units 356a-d remain energized, as YZ magnet quadrant 304 remains positioned substantially over YZ coil units 356a-d such that YZ coil units 356a-d are in a range of YZ magnet quadrant 304.

As the edge of the YZ magnet quadrant 304 approaches at least one new YZ coil unit and effectively leaves one or more YZ coil units, a switching event may happen as shown in FIG. 3C. That is, at a time t3, as YZ magnet quadrant 304 moves relative to coil array 350 along Y axis 358b, and approaches YZ coil units 356e, 356f, YZ coil units 356e, 356f may be energized. When YZ magnet quadrant 304 approaches YZ coil units 356e. 356f, YZ magnet quadrant 304 moves away from YZ coil unit 356c. As such, YZ coil unit 356c is no longer energized. In one embodiment, when YZ magnet quadrant 304 effectively reaches YZ coil units 356e, 356f, YZ coil units 356e, 356f may be energized while YZ coil 356c is no longer energized. It should be appreciated that when YZ magnet quadrant 304 effectively reaches YZ coil units 356e, 356f, YZ coil units 356e, 356f are within a range associated with YZ magnet quadrant 304. At a time t4, as shown in FIG. 3D, YZ magnet quadrant 304 moves further over YZ coil units 356e, 356f. According to the present invention, the current command to YZ coil unit 356c is smoothly ramped down to zero before the switching event, and the current commands to YZ coil units 356e, 356f are smoothly ramped up from zero to their appropriate value after the switching event. In this manner, the current command to coil units 356c, 356e, and 356f may all be substantially zero at the time of the switching event. Because the electrical switching occurs when the current is substantially zero, undesirable disturbances in the voltage and/or current may be reduced.

According to another embodiment of the present invention, when a magnet quadrant moves in a force direction, substantially energizing approaching coil units before switching off the coil units that the magnet quadrant effectively moves away from may lead to a relatively smoother force transition during a coil switching operation, but may utilize extra amplifiers. In such an embodiment, the commutated current amplitude may be increased gradually, e.g., smoothly, in a coil unit that a magnet quadrant is moving towards until the coil unit produces substantially nominal force, after which the commutated current amplitude may be reduced gradually, e.g., smoothly, in coil unit(s) that the magnet quadrant is moving away from. FIGS. 3E-3H are diagrammatic representations of a process of turning on extra coils under a magnet quadrant prior to a coil switching event in a force direction in accordance with an embodiment of the present invention. At a time t1, as shown in FIG. 3E, four YZ coil units 386a-d of an overall coil array 380, which are located substantially under a YZ magnet quadrant 384, may initially be energized. YZ coil units 386a-d are coils arranged to cooperate with YZ magnet quadrant 384 to create force in along a Y axis 388b and a Z axis 388c. YZ coil units 386a-d are located substantially under YZ magnet quadrant 384 relative to Z axis 388c.

At a time t2, as shown in FIG. 3F, YZ magnet quadrant 384 has moved along Y axis 388b relative to overall coil array 380 such that an edge of YZ magnet quadrant 384 is approaching YZ coil units 386e, 386f. When an edge or border of YZ magnet quadrant 384 is in proximity to YZ coil units 386e, 386f, YZ coil units 386e, 386f are within a range of YZ magnet quadrant 384. As such, YZ coil units 386e, 386f may be energized. Preferably, the current command to coils 386e, 386f is substantially zero when coils 386e, 386f are initially energized, and after energizing the current command may be smoothly ramped up to the nominal value. The range within which coil units 386e, 386f may be energized may vary depending upon the requirements of a particular system. For example, coil units 386e, 386f may be energized when YZ magnet quadrant 384 is within 2.5 millimeters (mm), 10 mm, or 15 mm if coil units 386e, 386f. In the described embodiment, YZ coil unit 386c remains energized, as part of YZ magnet quadrant 384 is still positioned substantially over YZ coil unit 386c, e.g., YZ coil unit 386c is still within a range associated with YZ magnet quadrant 384.

At a time t3, as shown in FIG. 3G, YZ magnet quadrant 384 has moved relative to overall coil array 380 such that YZ magnet quadrant 384 is positioned at least partially over YZ coil units 386e, 386f, and is no longer positioned over YZ coil unit 386c. In order to facilitate a relatively smoother force transition, YZ coil unit 386c remains energized. Coil unit 386c may be turned off when YZ magnet quadrant 384 is a particular distance away from coil unit 386c. It should be appreciated that the particular distance may vary, e.g., the particular distance may be 2.5 mm, 10 mm, or 15 mm in one embodiment. As YZ magnet quadrant 384 moves further away from YZ coil unit 386c, the current command to YZ coil unit 386c may be smoothly ramped down or reduced until the current command is substantially zero, and then YZ coil unit 386c may be turned off. At a time t4, as shown in FIG. 3H, coil unit 356c is no longer energized. YZ coil units 386a, 386b, 386d-f, each of which is located at least partially under YZ magnet quadrant 384, are energized at time t4.

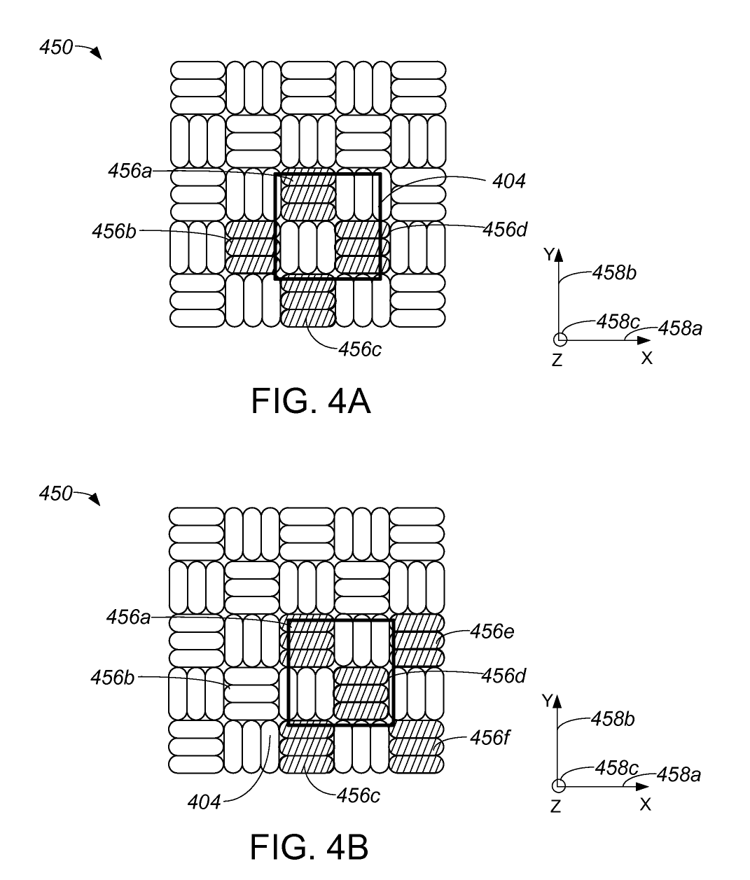

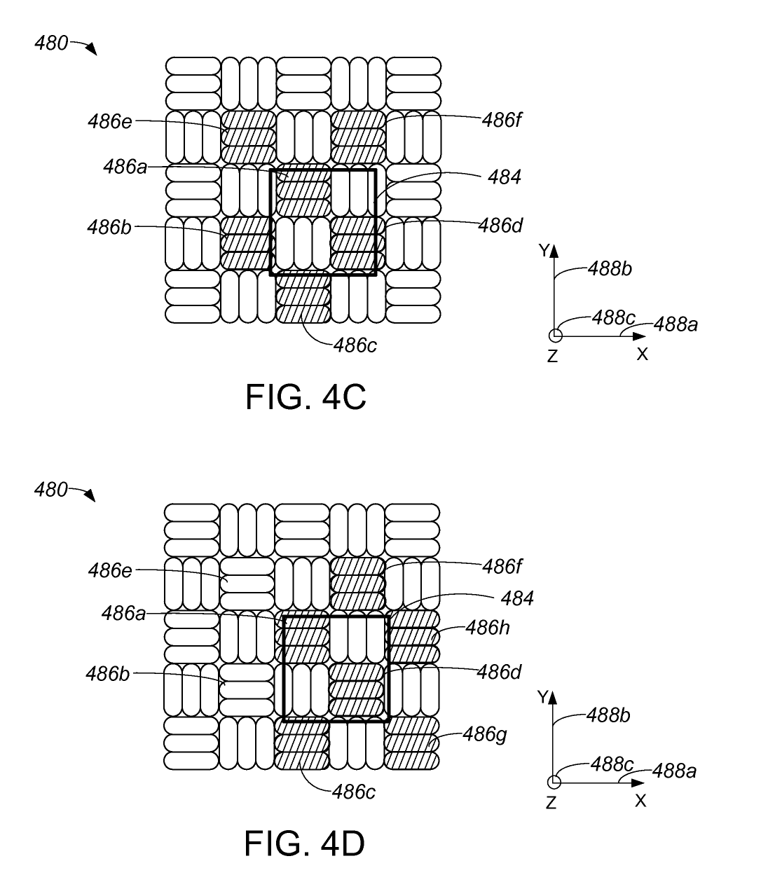

When a unit-by-unit switching event occurs with movement in a cross direction, e.g., an X direction for a YZ coil unit, end turns or turnaround portions of a coil may not produce as much useful force in an intended direction. End turns of a coil, as will be understood by those skilled in the art, are effectively the ends of the coils. As a result of end turns of a coil not producing as much useful force in an intended direction, a coil may be relatively freely switched off and on when substantially only the end turn portions of the coil are effectively covered by a magnet quadrant. FIGS. 4A and 4B are a diagrammatic representation of a process of turning on a substantially minimal number of coils, e.g., YZ coils, under a magnet quadrant, e.g., a YZ magnet quadrant, during a coil switching event in a cross direction in accordance with an embodiment of the present invention. At a time t1, as shown in FIG. 4A, a YZ magnet quadrant 404 is positioned over a coil array 450, relative to a Z axis 458c, such that YZ coil units 465a-d are energized. It should be appreciated that substantially only an end turn portion of YZ coil unit 456b is covered by YZ magnet quadrant 404. As YZ magnet quadrant 404 moves along an X axis 458a to the right, the current command to coil unit 456b may be smoothly reduced until it is substantially zero. Because only the end turns of coil unit 456b are interacting with magnet quadrant 404, reducing the current in coil unit 456b generally does not substantially alter the overall planar motor force output.

As YZ magnet quadrant 404 translates along X axis 458a, and covers end turns of YZ coil units 456e, 456f at a time t2, YZ coil units 456e, 456f are energized, as shown in FIG. 4B. Initially, the current command to YZ coil units 456e, 456f may be substantially zero, and after YZ coil units 456e, 456f are energized, their current commands may be smoothly ramped up to a nominal, or desired, value. Because portions of YZ coil unit 456b are no longer covered by YZ magnet quadrant 404, YZ coil unit 456b is no longer energized.

To facilitate a relatively smoother force transition during a coil switch or coil switching event, extra coils may be turned on or energized during a coil switch in a cross direction. FIGS. 4C and 4D are a diagrammatic representation of a process of turning on extra coil units in the proximity of a magnet quadrant during a coil switching event in a cross direction in accordance with an embodiment of the present invention. At a time t1, as shown in FIG. 4C, a YZ magnet quadrant 484 is positioned over a coil array 480, relative to a Z axis 488c, such that YZ coil units 485a-d are energized. In the embodiment as shown, although YZ magnet quadrant 484 is not positioned over YZ coil units 486e, 486f, YZ coil units 486e, 486f are relatively close to YZ magnet quadrant 484 and are, thus, turned on or energized. As such, a planar motor that includes YZ magnet quadrant 484 and YZ coil units 485a-d may be prepared for motion in either a positive Y direction or a negative Y direction substantially without the need for additional coil unit switching.

As YZ magnet quadrant 484 translates relative to an X axis 488a, YZ magnet quadrant 484 covers end turns of YZ coil units 486g, 486h at a time t2, YZ coil units 486g, 486h are energized, as shown in FIG. 4D. Because portions of YZ coil unit 458b are no longer covered by YZ magnet quadrant 484, YZ coil unit 486b is no longer energized. In addition, as YZ coil unit 486e is no longer in proximity to YZ magnet quadrant 484, YZ coil unit 486e is also no longer energized at time t2.

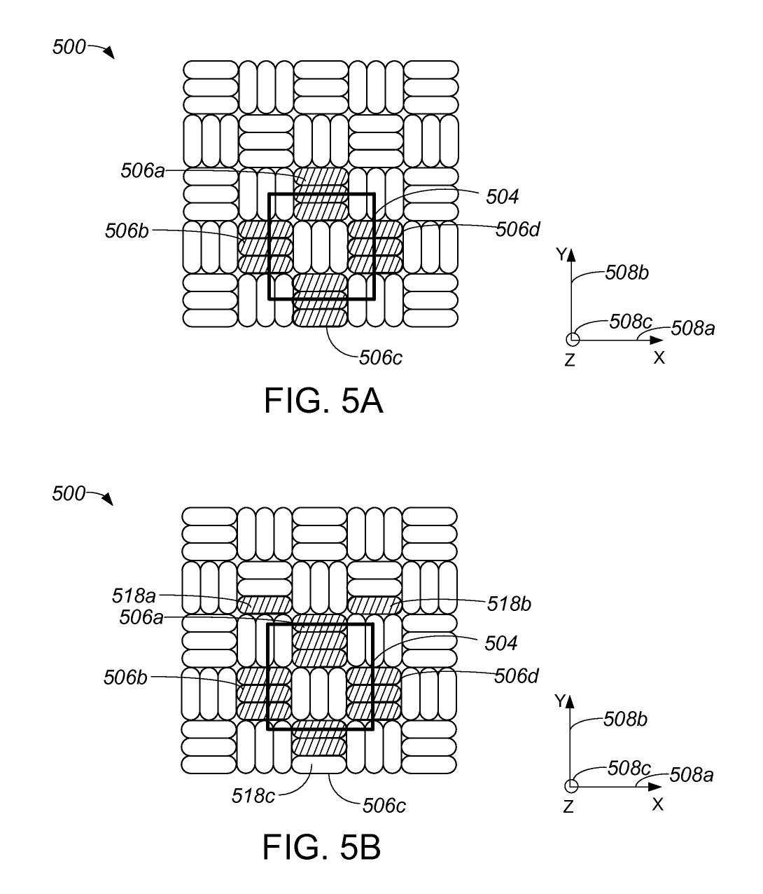

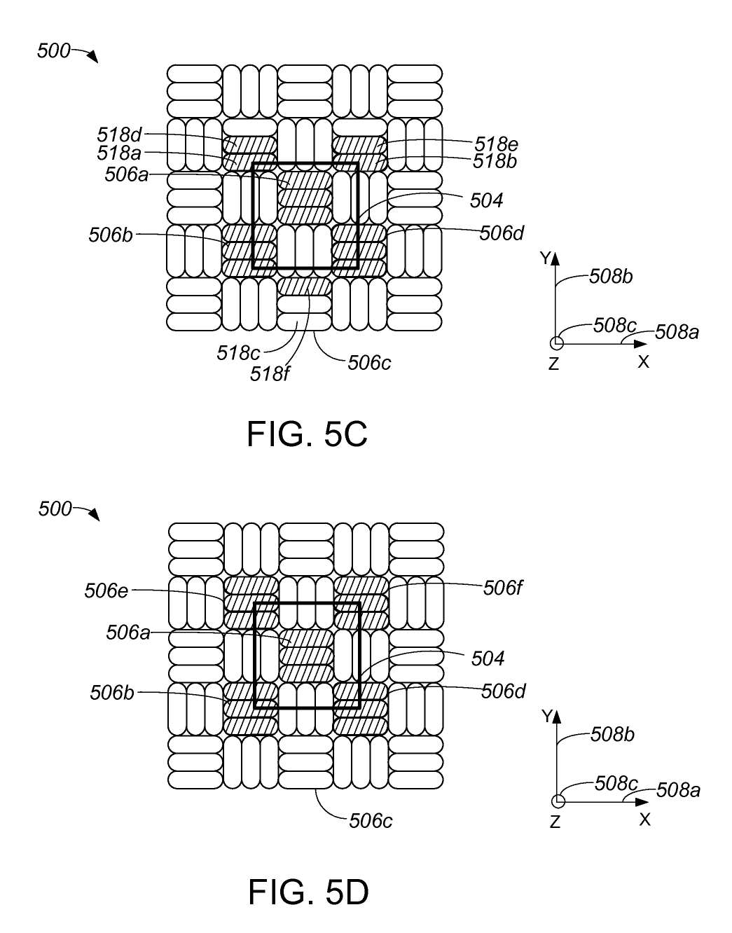

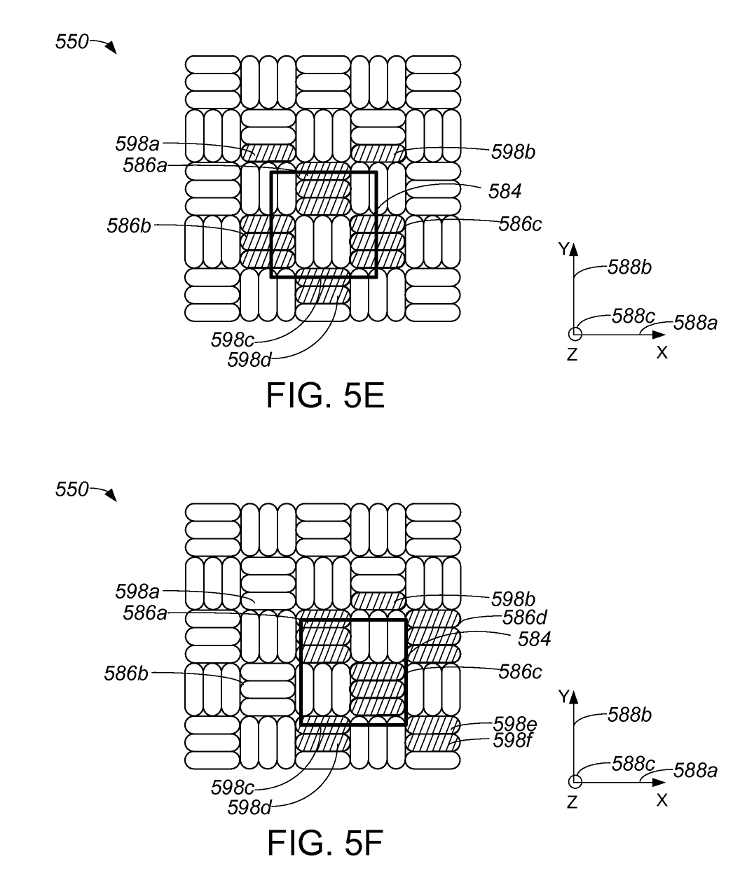

In lieu of a unit-by-unit coil switch, a coil-by-coil switch may be implemented. That is, rather than energizing all coils in a coil unit during a switch, single coils of a coil unit may instead be energized during a switch. Single coils may also be turned off during a switch. FIGS. 5A-5D are a diagrammatic representation of a process of turning on at least one coil outside of a magnet quadrant during a coil-by-coil coil switch in a force direction in accordance with an embodiment of the present invention. A relatively significant amount of magnetic flux may extend out of a magnet quadrant by as far as approximately a coil width in a motor force direction. Such magnetic flux may be due to an edge effect. To improve the smoothness of a motor force, at least one coil that is located substantially out from under a magnet quadrant may be energized. As illustrated in FIGS. 5A-5D, locations of energized coils are shown as a magnet quadrant moves in a force direction. Compared to a unit-by-unit switch, a coil-by-coil switch typically provides improved efficiency and flexibility with a lower number of amplifiers.

At a time t1, as shown in FIG. 5A, a YZ magnet quadrant 504 is positioned substantially over an overall coil array 500 relative to a Z axis 508c such that YZ magnet quadrant 504 at least partially overlays YZ coil units 506a-d, and YZ coil units 506a-d are energized. At a time t2, as shown in FIG. 5B, YZ magnet quadrant 504 moves along a Y axis 508b, i.e., in a force direction. When YZ magnet quadrant 504 moves over overall coil array 500 along Y axis 508b, a coil-by-coil switch may occur such that YZ coils 518a, 518b which are in proximity to an edge of YZ magnet quadrant 504 are energized, while a YZ coil 518c, which is part of YZ coil unit 506c, is turned off. As YZ magnet quadrant 504 continues to move in a force direction, coil-by-coil switches may continue. At a time t3, as shown in FIG. 5C, YZ coils 518d, 518e are energized, while coil 518f of YZ coil unit 506c is turned off. At a time t4, as shown in FIG. 5D, YZ magnet quadrant 504 has moved still further in a force direction, and all coils in YZ coil units 506e, 506f are energized, while no coils in YZ coil unit 506c are energized. As mentioned above, the current command to each coil 518a, 518b, 518d, 518e may be substantially zero when each coil is initially energized, and after energizing, the current command may be smoothly ramped up to a desired, or nominal value. Similarly, the current command for each coil 518c, 518f may be smoothly ramped down to substantially zero before each coil 518c, 518f is switched off.

Coil-by-coil switching may also occur when a magnet quadrant moves in a cross direction. FIGS. 5E and 5F are a diagrammatic representation of a process of performing a coil-by-coil switch in a cross direction in accordance with an embodiment of the present invention. As will be appreciated by those skilled in the art, end turns of a coil generally do not produce significant force in an intended direction. Hence, no extra coils may need to be energized or turned on to maintain force uniformity during coil switching.

At a time t1, as shown in FIG. 5E, a YZ magnet quadrant 584 is positioned substantially over an overall coil 550 relative to a Z axis 588c such that YZ magnet quadrant 504 at least partially overlays YZ coil units 586a-c. As a result, YZ coil units 506a-c are energized. YZ magnet quadrant 584 also overlays YZ coil 598c, which is energized. YZ coils 598a, 598b which are in proximity to YZ magnet quadrant 584, are also energized. In the embodiment as shown, YZ coil 598d is also energized, but the overall YZ coil unit which includes YZ coil 598c and YZ coil 598d is not energized.

At a time t2, as shown in FIG. 5F, YZ magnet quadrant 584 moves in a cross direction, or relative to an X axis 588a. When YZ magnet quadrant 584 moves over overall coil array 550 along X axis 588b, a coil-by-coil switch may occur such that YZ coils 598e, 598f which are in proximity to an edge of YZ magnet quadrant 554 are energized, while YZ coil 598a, which is no longer in proximity to an edge of YZ magnet quadrant 554, is turned off. As mentioned above, the current command to each coil 598e, 598f may be substantially zero when each coil 5983, 598f is initially energized, and after energizing, the current command may be smoothly ramped up to a desired, or nominal, value. Similarly, the current command for coil 598a may be smoothly ramped down to substantially zero before coil 598a is switched off.

The number of amplifiers, e.g., the number of three-phase amplifiers, used to substantially control coils may effectively be minimized by using the same amplifiers to substantially control different coils. That is, an amplifier that causes current to be provided to a first coil may be used to provide current to a second coil once it is no longer necessary to provide current to the first coil. In one embodiment, approximately eighteen three-phase amplifiers may be used to provide current to an overall coil array which is used with two YZ magnet quadrants and two XZ magnet quadrants, with nine three-phase amplifiers used to provide current to the YZ coil and nine three-phase amplifiers used to provide current to the XZ coils. It should be appreciated that more than eighteen or fewer than eighteen three-phase amplifiers may be used to provide current to an overall coil array. By way of example, for an embodiment in which single-phase amplifiers are used to provide current to a coil array used with a magnet array that includes two YZ magnet quadrants and two XZ magnet quadrants of the type shown above in FIGS. 3A-3H, FIGS. 4A-4D, and FIGS. 5A-5F, a total of approximately twenty-four to approximately thirty-six amplifiers may be used to provide current to an overall coil array depending on the specific requirements of a given application.

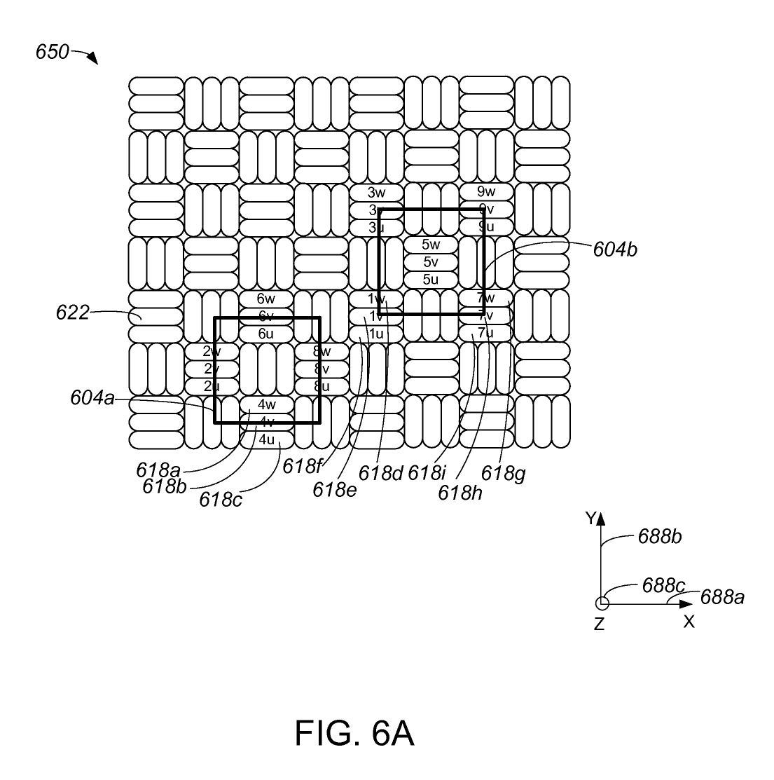

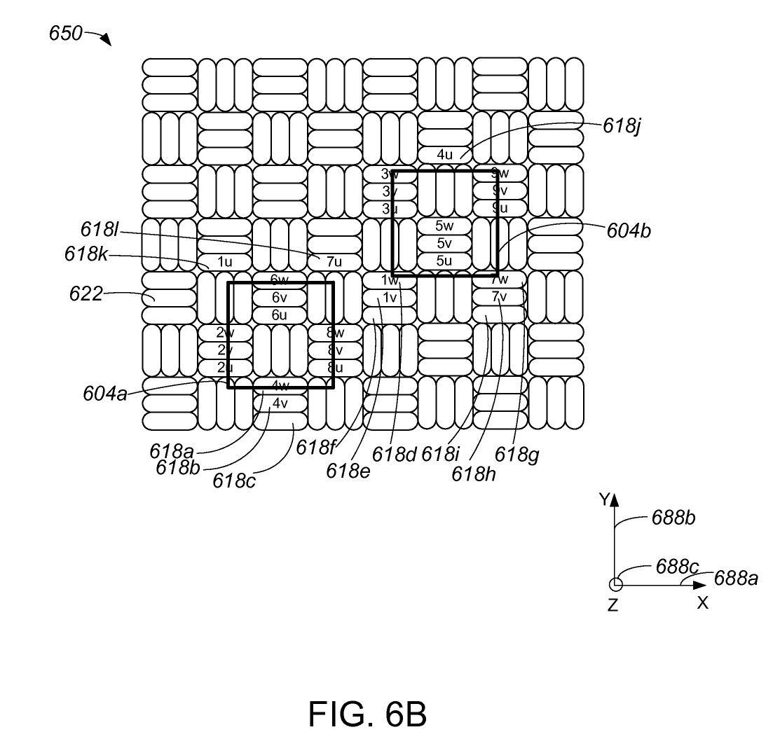

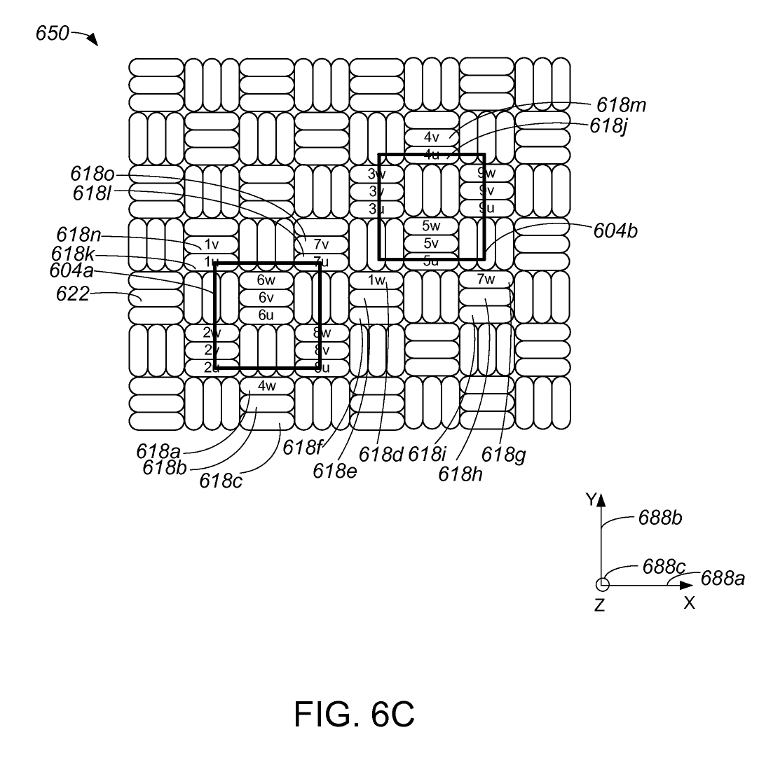

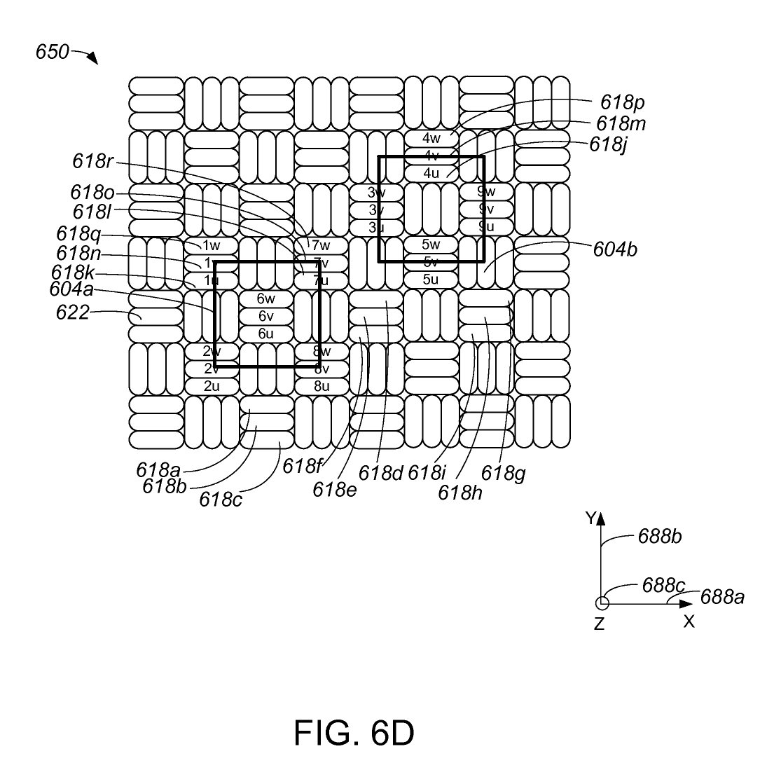

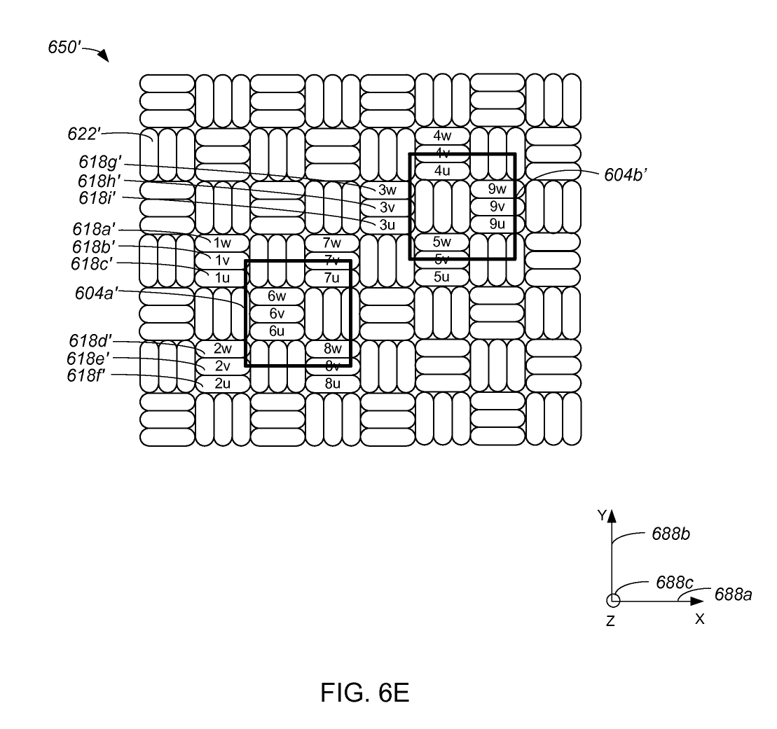

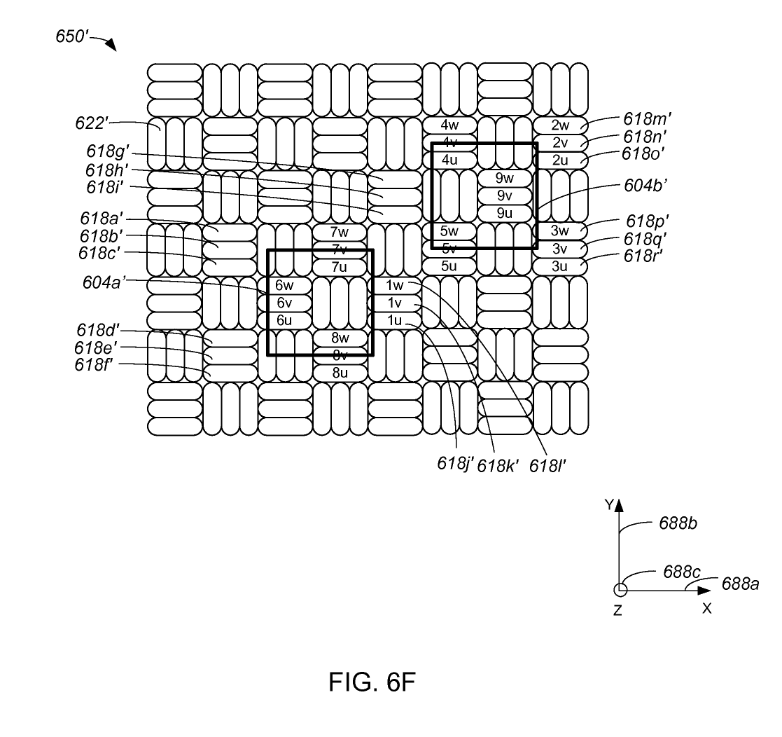

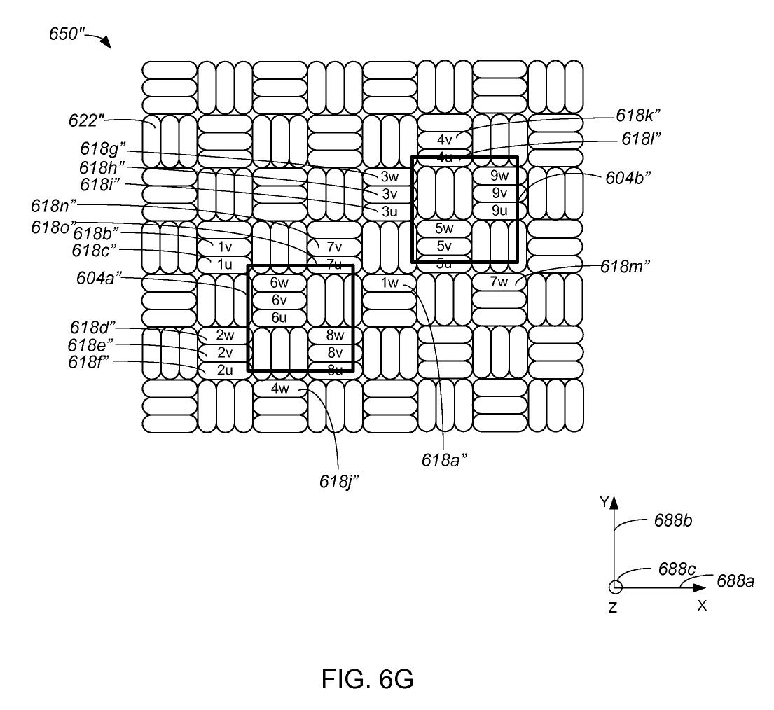

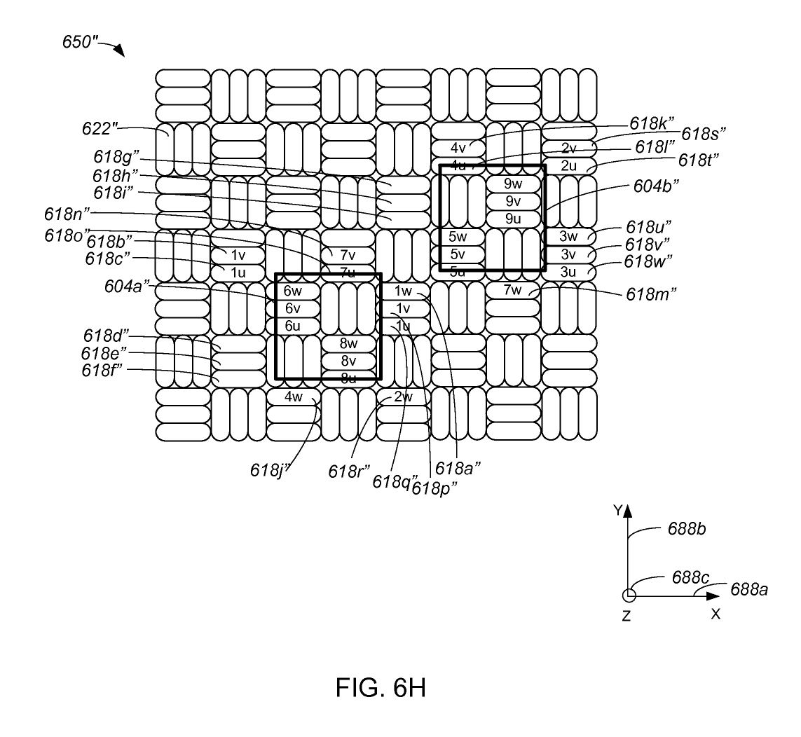

With reference to FIGS. 6A-6D, coil-by-coil switching with respect to a force direction will be described in accordance with an embodiment of the present invention. A coil array 650 includes YZ coils 618 and XZ coils 622 that are provided with current, or energized, using a plurality of three-phase amplifiers, e.g., nine three-phase amplifiers. Coil array 650 is positioned at a distance from magnet quadrants 604a, 604b of a magnet array relative to a Z axis 688c. Magnet quadrants 604a, 604b are YZ magnet quadrants, and are arranged to cooperate with YZ coils 618 to allow a planar motor, which includes magnet quadrants 602a, 604b and coil array 650, to move in a force direction, e.g., relative to a Y axis 688b and/or Z axis 688c.

In the described embodiment, nine three phase-amplifiers are used to provide current to coil array 650 for YZ coils 618, and nine three-phase amplifiers are used to provide current to coil array 650 for XZ coils 622. It should be appreciated, however, that more than nine three-phase amplifiers or fewer than nine three-phase amplifiers may be used to provide current for YZ coils 618 and more than nine three-phase amplifiers or fewer than nine three-phase amplifiers may be used to provide current for XZ coils 622.

The nine amplifiers used to provide current to YZ coils 618 such that YZ coils 618 may be energized are identified in FIG. 6A by numbers “1” through “9”. As shown in FIG. 6A, at a time t1, YZ coils 618 that are at least partially located in a range or region associated with YZ magnet quadrants 604a, 604b are energized. Energized YZ coils include YZ coils 618a-c which are energized by amplifier “4”, YZ coils 618d-f which are energized by amplifier “1”, and YZ coils 618g-i which are energized by amplifier “7”.

At a time t2, as shown in FIG. 6B, YZ magnet quadrants 604a, 604b have moved relative to Y axis 688b by approximately one coil width. The movement of YZ magnet quadrants 604a, 604b causes one output phase from amplifier “1” to switch from providing current to YZ coil 618f to providing current to YZ coil 618k, as coil 618f is no longer in a range associated with either YZ magnet quadrant 604a or YZ magnet quadrant 604b, while YZ coil 618k is in the range associated with YZ magnet quadrant 604a. Similarly, one phase of amplifier “4” switches at time t2 from providing current to YZ coil 618c to providing current to YZ coil 618j, and one phase of amplifier “7” switches at time t2 from providing current to YZ coil 618i to providing current to YZ coil 618l.

It should be appreciated that, in one embodiment, prior to one phase of an amplifier switching from providing current to one coil, e.g., YZ coil 618f, to providing current to another coil, e.g., YZ coil 618k, the amplifier may smoothly reduce the output current of that phase to substantially zero, e.g., until YZ coil 618f is effectively turned off. YZ coil 618f may be substantially turned off, and the associated amplifier may switch to providing current to coil 618k, when a pre-determined switching location is reached by YZ magnet quadrants 604a, 604b.

At a time t3, as shown in FIG. 6C, YZ magnet quadrants 604a, 604b have further moved relative to Y axis 688b by approximately one coil width. The movement of YZ magnet quadrants 604a, 604b causes a second phase of amplifier “1” to switch from providing current to YZ coil 618e to providing current to YZ coil 618n, as YZ coil 618e is no longer in a range associated with either YZ magnet quadrant 604a or YZ magnet quadrant 604b, while coil 618n is in the range associated with YZ magnet quadrant 604a. Similarly, one phase of amplifier “4” switches at time t3 from providing current to YZ coil 618b to providing current to YZ coil 618m, and one phase of amplifier “7” switches at time t3 from providing current to YZ coil 618h to providing current to YZ coil 6180.

YZ magnet quadrants 604a, 604b continue to move relative to Y axis 688b, and at a time t4, are positioned as shown in FIG. 6D. The movement of YZ magnet quadrants 604a, 604b causes a third phase of amplifier “1” to switch from providing current to YZ coil 618d to providing current to YZ coil 618q, as YZ coil 618d is no longer in a range associated with either YZ magnet quadrant 604a or YZ magnet quadrant 604b, while coil 618q is in the range associated with YZ magnet quadrant 604a. Similarly, one phase of amplifier “4” switches at time t4 from providing current to YZ coil 618a to providing current to YZ coil 618p, and one phase of amplifier “7” switches at time t4 from providing current to YZ coil 618g to providing current to YZ coil 618r. As previously mentioned, the current commands may be smoothly ramped between substantially zero and a desired or nominal value to avoid force disturbances on a stage.

FIGS. 6E and 6F are a diagrammatic representation of a process of coil switching for two YZ magnet quadrants of a planar motor for movement in a cross direction in accordance with an embodiment of the present invention. A coil array 650′ includes YZ coils 618′ and XZ coils 622′ that are provided with current, or energized, using a plurality of three-phase amplifiers, e.g., nine three-phase amplifiers. Coil array 650′ is positioned at a distance from magnet quadrants 604a′, 604b′ of a magnet array relative to Z axis 688c. Magnet quadrants 604a′, 604b′ are YZ magnet quadrants, and are arranged to cooperate with YZ coils 618′ to allow a planar motor, which includes magnet quadrants 602a′, 604b and coil array 650, to move in a force direction, e.g., relative to Y axis 688b, and in a cross direction, e.g., relative to X axis 688a.

In the described embodiment, nine three phase-amplifiers are used to provide current to coil array 650′ for YZ coils 618′, and nine three-phase amplifiers are used to provide current to coil array 650′ for XZ coils 622′. It should be appreciated, however, that more than nine three-phase amplifiers or fewer than nine three-phase amplifiers may be used to provide current for YZ coils 618′ and more than nine three-phase amplifiers or fewer than nine three-phase amplifiers may be used to provide current for XZ coils 622′.

The nine amplifiers used to provide current to YZ coils 618′ such that YZ coils 618′ may be energized are identified in FIG. 6E by numbers “1” through “9”. As shown in FIG. 6E, at a time t1, YZ coils 618′ that are at least partially located in a range or region associated with YZ magnet quadrants 604a′, 604b′ are energized. Energized YZ coils include YZ coils 618a′-c′ which are energized by amplifier “1”, YZ coils 618d′-f′ which are energized by amplifier “2”, and YZ coils 618g′-i′ which are energized by amplifier “3”.

At a time t2, as shown in FIG. 6F, YZ magnet quadrants 604a′, 604b′ have moved in a cross direction, or relative to X axis 688a by approximately one coil width. The movement of YZ magnet quadrants 604a′, 604b′ causes amplifier “1” to switch from providing current to YZ coils 618a′-c′ to providing current to YZ coils 618j′-l′, as YZ coils 618a′-c′ are no longer in a range associated with either YZ magnet quadrant 604a′ or YZ magnet quadrant 604b′, while YZ coils 618j′-l′ are in the range associated with YZ magnet quadrant 604a′. Similarly, amplifier “2” switches at time t2 from providing current to YZ coils 618d′-f′ to providing current to YZ coils 618m′-o′, and amplifier “3” switches at time t2 from providing current to YZ coils 618g′-i′ to providing current to YZ coils 618p′-r′.

FIGS. 6G and 6H are a diagrammatic representation of coil switching for two YZ magnet quadrants of a planar motor for movement in a cross direction in accordance with an embodiment of the present invention. A coil array 650″ includes YZ coils 618″ and XZ coils 622″ that are provided with current, or energized, using a plurality of three-phase amplifiers, e.g., nine three-phase amplifiers. It should be appreciated, however, that more than nine or fewer than nine three-phase amplifiers may be used to provide current for YZ coils 618″ and more than nine or fewer than nine three-phase amplifiers may be used to provide current for XZ coils 622″. Coil array 650″ is positioned at a distance from magnet quadrants 604a″, 604b″ of a magnet array relative to Z axis 688c. Magnet quadrants 604a″, 604b″ are YZ magnet quadrants, and are arranged to cooperate with YZ coils 618″ to allow a planar motor, which includes magnet quadrants 602a″, 604b″ and coil array 650″, to move in a cross direction, e.g., relative to X axis 688a.

In the described embodiment, nine amplifiers may be used to provide current to YZ coils 618″ such that YZ coils 618″ may be energized. The amplifiers are identified in FIG. 6G by numbers “1” through “9”. As shown in FIG. 6G, at a time t1, YZ coils 618″ that are at least partially located in a range or region associated with YZ magnet quadrants 604a″, 604b″ are energized. Energized YZ coils include YZ coils 618a″-o″. YZ coils 618a″-c″ are energized by amplifier “1”, YZ coils 618d″-f″ are energized by amplifier “2”, YZ coils 618g″-i″ are energized by amplifier “3”, YZ coils 618j-j″ are energized by amplifier “4”, and YZ coils 618m″-o″ are energized by amplifier “7”.

At a time t2, as shown in FIG. 6H, YZ magnet quadrants 604a″, 604b″ have moved in a cross direction. The movement of YZ magnet quadrants 604a″, 604b″ causes amplifier “1” to switch from providing current to YZ coils 618a″-c″ to providing current to YZ coils 618a″, 618p″, and 618q″. The movement of YZ magnet quadrants 604a″, 604b″ also causes amplifier “2” to switch from providing current to YZ coils 618d″-f′ to providing current to YZ coils 618r″-t″, and amplifier “3” to switch from providing current to YZ coils 618g″-i″ to providing current to YZ coils 618u″-w″.

As discussed above, coil-by-coil switching may occur for two YZ magnet quadrants of a planar motor. It should be appreciated that a total number of energized coils associated with YZ magnet quadrants may remain substantially the same. For example, approximately twenty seven coils of coil array 650 as discussed with respect to FIGS. 6A-6D may be energized at time t1, at time t2, at time t3, and at time t4. Depending on the specific application, these twenty-seven coils may be driven by nine three-phase amplifiers as described above, or by twenty-seven independent, single-phase amplifiers. A similar arrangement may be used for driving the XZ coils which operate in a corresponding manner with XZ magnet quadrants, which are not shown in the figures.

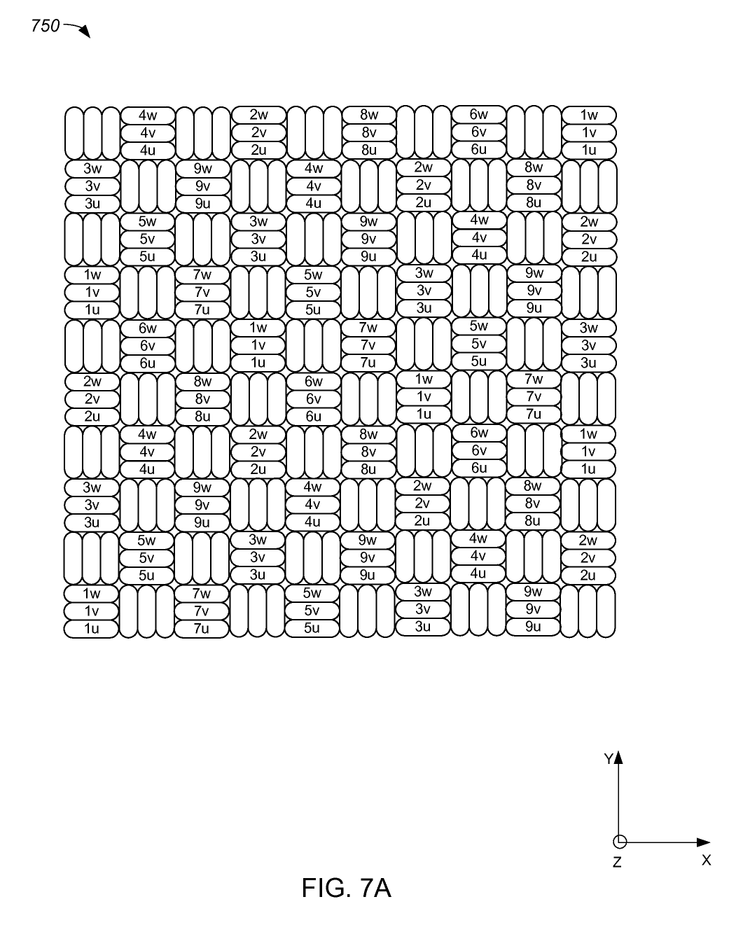

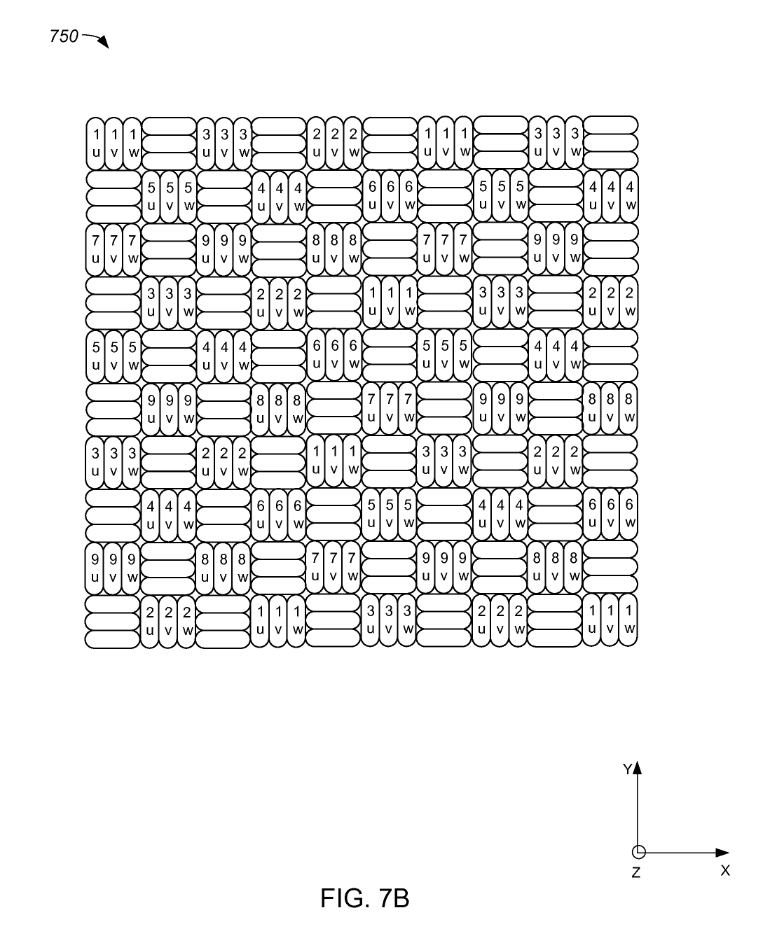

In one embodiment, substantially every coil associated with a planar motor may connect to an amplifier in cases of both unit-by-unit and coil-by-coil switching. FIG. 7A is a diagrammatic representation of a YZ coil and amplifier connection layout in accordance with an embodiment of the present invention. A coil array 750 includes YZ coils which are shown with their associated amplifier connections. FIG. 7B is a diagrammatic representation of a XZ coil and amplifier connection layout in accordance with an embodiment of the present invention. Coil array 750 includes XZ coils which are shown with their amplifier connections. In the described embodiment, coil array 750 is associated with nine three-phase amplifiers which provide current to YZ coils, and nine three-phase amplifiers which provide current to XZ coils. In alternative embodiments, more or fewer than nine three-phase amplifiers may be used for each of the YZ and XZ coils.

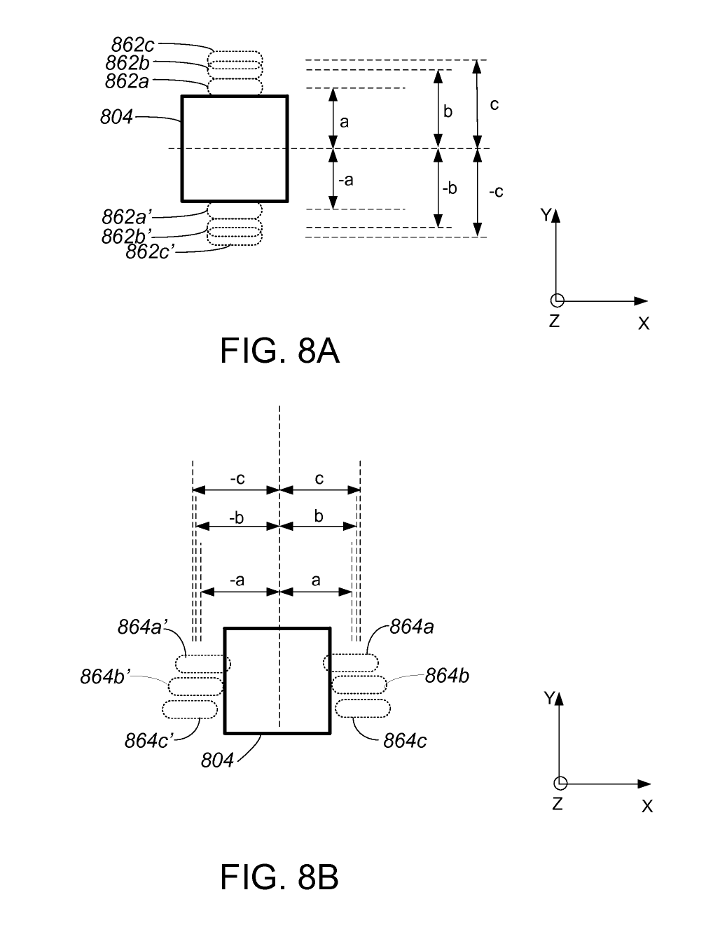

A coil current command scaling factor may be used to smooth out a motor force during coil switching. In general, a coil current command scaling factor may vary based on a distance of a coil, i.e., a coil that is subject to the coil current command, from a magnet quadrant with respect to an X axis and/or a Y axis. FIG. 8A is a diagrammatic representation of a coil current scaling in a force direction in accordance with an embodiment of the present invention. Coil positions 862a-c, 862a′-c′ represent coil positions relative to a magnet quadrant 804 as shown. In the described embodiment, coils positions 862a-c, 862a′-c′ are relative positions of individual YZ coils arranged to generate force in at least a Y direction, or a motor force direction.

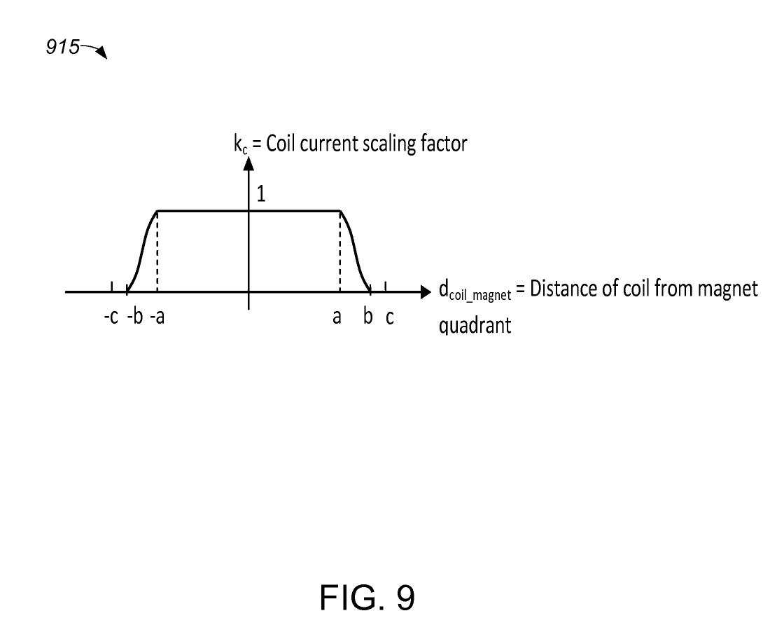

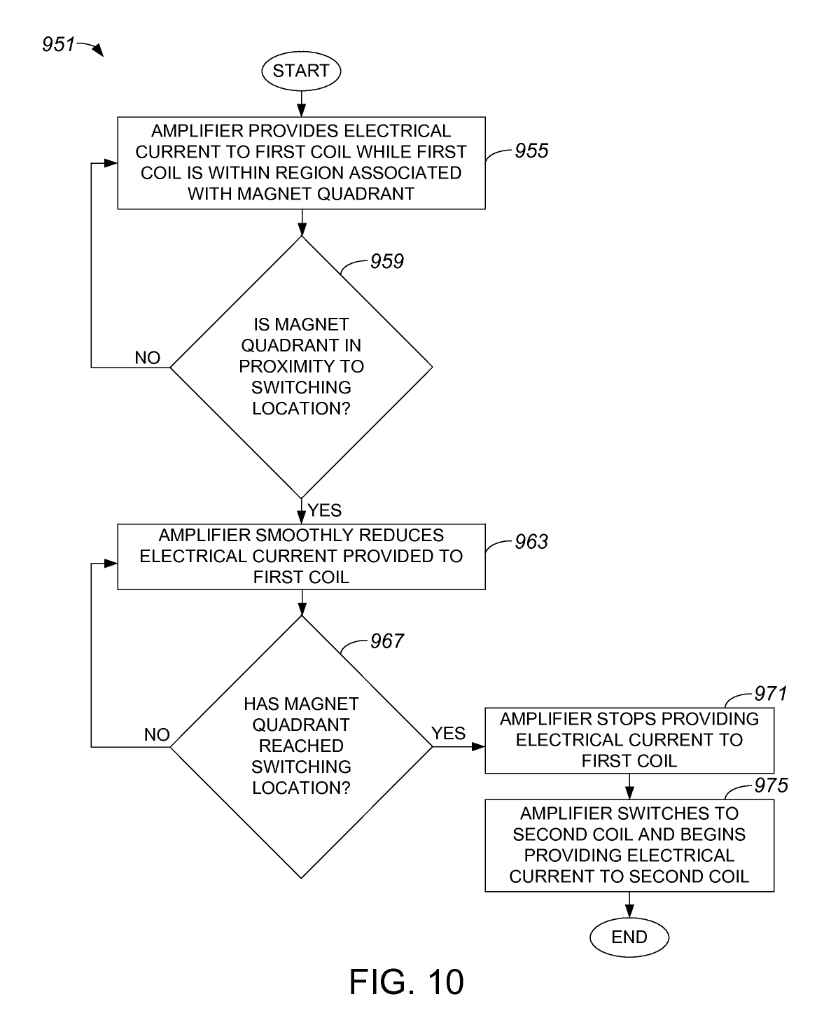

In a motor force direction, to accommodate an edge effect of magnet quadrant 804, a coil current may gradually be turned down or reduced when a particular coil is positioned substantially further out of the range of magnet quadrant 804. Centerlines of coil positions 862a, 862a′ are located at a distance “a” from a centerline of magnet quadrant 804, centerlines of coil positions 862b, 862b′ are located at a distance “b” from the centerline of magnet quadrant 804, and centerlines of coil positions 862c, 862c′ are located at a distance “c” from the centerline of magnet quadrant 804. As shown in a plot 915 of FIG. 9, a coil scaling factor may have a value of approximately one when a distance from a centerline of a coil to magnet quadrant 804, e.g., &oil magnet, corresponds to distance equal to or less than “a.”

Coil current is gradually reduced until a distance between a coil and magnet quadrant 804 reaches distance “b.” That is, coils (not shown) in coil positions 862b, 862b′ will have no coil current provided. In one embodiment, a difference between “a” and “b” may be approximately half of a coil width. In another embodiment, a difference between “a” and “b” may be a few millimeters or less.

In a motor force direction, to accommodate an edge effect of a corresponding magnet array, a coil current may gradually be turned down in coils (not shown) when the coils are between coil positions 862a, 862a′ and coil positions 862b, 862b′, respectively, when the coils have moved substantially out from under magnet quadrant 804. Coil positions 862b, 862b′ are shown as being approximately a coil-width away from magnet quadrant 804. In one embodiment, once coils (not shown) have moved into coil positions 862b, 862b′, the coil current is substantially zero, as indicated in plot 915 of FIG. 9. Coil positions 862c, 862c′ are still further away from the magnet quadrant 804. In preferred embodiments, coil positions 862c, 862c′ may be used as the locations where amplifiers connections to coils are switched on or off, and the corresponding amplifier may connected to or disconnected from another coil (not shown) which is in a similar position relative to a corresponding magnet quadrant (not shown). From a smoothing function shown in plot 915 of FIG. 9, a coil current scaling factor k_{c,p}, may be used for relative motion in the force direction.

With reference to FIG. 9, when a coil is located in a magnetic flux sensitive area of an associated magnet quadrant, when the relative position of the coil and magnet centers, d_{coil}_{_{—}}_{magnet} is between “−a” and “a”, its current command will not be compromised, e.g., the current scaling factor k_{cp} is approximately one. When the coil is effectively slightly away from the flux sensitive area, e.g., when d coil magnet is between “−a” and “−b” or between “a” and “b”, its current command may be gradually reduced to a value less than one. When a coil is relatively far away from the magnet quadrant, e.g., when d_{coil}_{_{—}}_{magnet} is between “−b” and “−c” or between “b” and “c”, then the coil current may be substantially zero. When the coil is at a switching position, e.g., d_{coil}_{_{—}}_{magnet} is approximately “−c” or “c”, its associated amplifier may be electrically switched to energize another coil.

Referring next to FIG. 8B, coil scaling in a cross direction will be described. Once substantially only an end turn section of a coil position 864a, 864a′ is covered by magnet quadrant 804, coils (not shown) in coil positions 864a, 864a′ generally do not generate much force in the intended direction, e.g., a Y direction, and coils in coil positions 864a, 864a′ may be gradually turned off. Coils (not shown) in coil positions 864b, 864b′ are substantially completely out of the coverage range of magnet quadrant 804, and have no current provided thereto. Coils (not shown) in coil positions 864c, 864c′ which are moved even further away from magnet quadrant 804 are such that an amplifier connection to the coils in coil positions 864c, 864c′ may be electrically switched on or off, and, as such, and an associated amplifier is effectively free to disconnect from or connect to another coil (not shown).

As a stage that is coupled to a moving magnet planar motor generally moves in both an X direction and a Y direction, or along an X-axis and a Y-axis, an overall coil current command scaling factor for smooth switching may be the product of scaling factors in both a motor force direction and a cross direction, as follows:

k_{c}=k_{c,p}·k_{c,n}

k_{c} is an overall coil current command scaling factor, while k_{c,p} is a coil current command scaling factor in a motor force direction and k_{c,n} is a coil current command scaling factor in a cross direction. As shown in plot 915 of FIG. 9, it is generally preferable if the mathematical function defining the scaling factors k_{c,p} and k_{c,n} is continuous and differentiable, i.e., smooth, to substantially avoid any discontinuities or sudden changes in the coil current commands.

While an overall coil current command scaling factor for smooth switching may be a product of scaling factors in both a motor force direction and a cross direction, it should be appreciated that an overall coil current command scaling factor is not limited to being a product of scaling factors in both a motor force direction and a cross direction. By way of example, an overall coil current command scaling factor may be a function of the scaling factors in a motor force direction and a cross direction in which one of the scaling factors is weighted more than the other.

A current command for a specific coil may depend, at least in part, on the phase of a coil and its associated scaling factor. For example, a current command for a u-phase coil j may be as follows:

l_{u,j}=lᵤ·k_{c,j}=lᵤ·k_{c,p,j}·k_{c,n,j}

where t is a nominal commutated current command, as mentioned above, and k_{c,j} is its overall scaling factor that depends on the relative position of the coil and the associated magnet array.

Referring next to FIG. 10, a method of controlling an amplifier that is suitable for switching coils will be described in accordance with an embodiment of the present invention. A method 951 of controlling an amplifier begins at step 955 in which an amplifier provides electrical current to a first coil while the first coil is within a region associated with a magnet quadrant. The first coil is part of a coil array which, together with a magnet array that includes the magnet quadrant, forms at least a portion of a planar motor that generates force arranged to drive a stage.

A determination is made in step 959 as to whether the magnet quadrant is in proximity to a switching location. A switching location may be a location which, when reached by the magnet quadrant, effectively triggers or otherwise causes the amplifier to switch from providing electrical current to the first coil to providing electrical current to a second coil. In one embodiment, such a determination may involve determining when the stage has moved past a switching location.

If it is determined in step 959 that the magnet quadrant is not in proximity to the switching location, process flow returns to step 955 in which the amplifier continues to provide electrical current to the first coil. Alternatively, if it is determined in step 959 that the magnet quadrant is in proximity to the switching location, then the control software commands the amplifier to begin to smoothly reduce the electrical current provided to the first coil in step 963. If the current reduction is applied in a location where the coil does not contribute a large force to driving the stage, the effect on the overall stage control will be sufficiently small. Smoothly reducing the electrical current in the coil generally causes the force generated using the coil to be smoothly reduced. Smoothly reducing the electrical current provided to the coil generally includes the application of a coil current command scaling factor, as discussed above with respect to FIGS. 8A, 8B, and 9.

After the amplifier smoothly reduces the electrical current provided to the first coil, it is determined in step 967 whether the magnet quadrant has reached the switching location. If the determination is that the magnet quadrant has not reached the switching location, the electrical current provided to the first coil continues to be smoothly reduced in step 963 or maintained at a substantially zero value.

Alternatively, if the determination in step 967 is that the magnet quadrant has reached the switching location, the amplifier stops providing electrical current to the first coil in step 971, and the first coil is effectively de-energized or turned off. Then, in step 975, the amplifier switches to the second coil and begins providing electrical current to the second coil. In one embodiment, providing electrical current to the second coil includes beginning with a substantially zero electrical current and then smoothly increasing the electrical current to the second coil such that a force generated by the second coil smoothly increases after the magnet quadrant moves past the switching location. Once the amplifier begins providing electrical current to the second coil, the method of controlling an amplifier is completed.

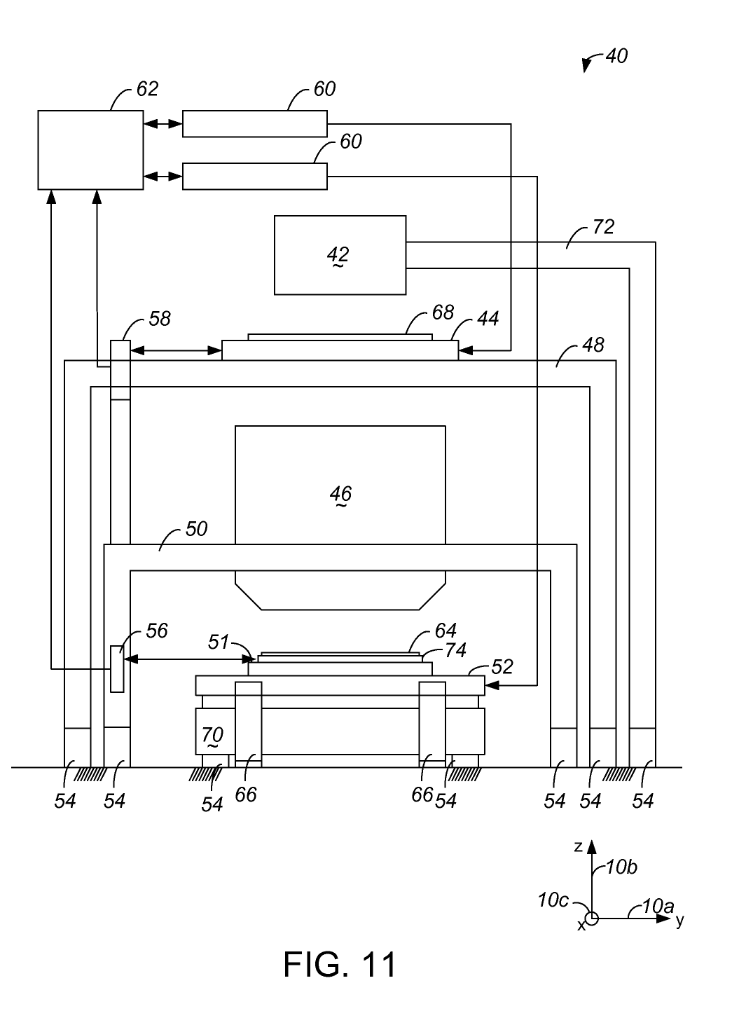

With reference to FIG. 11, a photolithography apparatus that may utilize a simple and deterministic formulation for coil switching that is efficient, uses a relatively low number of amplifiers, and generates relatively low heat will be described in accordance with an embodiment of the present invention. A photolithography apparatus (exposure apparatus) 40 includes a wafer positioning stage 52 that may be driven by a planar motor (not shown), as well as a wafer table 51 that is magnetically coupled to wafer positioning stage 52 by utilizing a short stroke actuator. The planar motor which drives wafer positioning stage 52 generally uses an electromagnetic force generated by magnets and corresponding armature coils arranged in two dimensions.

A wafer 64 is held in place on a wafer holder or chuck 74 which is coupled to wafer table 51. Wafer positioning stage 52 is arranged to move in multiple degrees of freedom, e.g., in up to six degrees of freedom, under the control of a control unit 60 and a system controller 62. In one embodiment, wafer positioning stage 52 may include a plurality of actuators and have a configuration as described above. The movement of wafer positioning stage 52 allows wafer 64 to be positioned at a desired position and orientation relative to a projection optical system 46.

Wafer table 51 may be levitated in a z-direction 10b by any number of voice coil motors (not shown), e.g., three voice coil motors. In one described embodiment, at least three magnetic bearings (not shown) couple and move wafer table 51 along a y-axis 10a. The motor array of wafer positioning stage 52 is typically supported by a base 70. Base 70 is supported to a ground via isolators 54. Reaction forces generated by motion of wafer stage 52 may be mechanically released to a ground surface through a frame 66. One suitable frame 66 is described in JP Hei 8-166475 and U.S. Pat. No. 5,528,118, which are each herein incorporated by reference in their entireties. In alternate embodiments, the wafer positioning stage 52 may be driven in 3 or 6 degrees of freedom by a planar motor including the features described above.

An illumination system 42 is supported by a frame 72. Frame 72 is supported to the ground via isolators 54. Illumination system 42 includes an illumination source, which may provide a beam of light that may be reflected off of a reticle. In one embodiment, illumination system 42 may be arranged to project a radiant energy, e.g., light, through a mask pattern on a reticle 68 that is supported by and scanned using a reticle stage 44 which may include a coarse stage and a fine stage, or which may be a single, monolithic stage. The radiant energy is focused through projection optical system 46, which is supported on a projection optics frame 50 and may be supported the ground through isolators 54. Suitable isolators 54 include those described in JP Hei 8-330224 and U.S. Pat. No. 5,874,820, which are each incorporated herein by reference in their entireties.

A first interferometer 56 is supported on projection optics frame 50, and functions to detect the position of wafer table 51. Interferometer 56 outputs information on the position of wafer table 51 to system controller 62. In one embodiment, wafer table 51 has a force damper which reduces vibrations associated with wafer table 51 such that interferometer 56 may accurately detect the position of wafer table 51. A second interferometer 58 is supported on projection optical system 46, and detects the position of reticle stage 44 which supports a reticle 68. Interferometer 58 also outputs position information to system controller 62. In other embodiments, precision encoders may be used to detect the position of wafer table 51 and reticle stage 44 in place of interferometer 58.

It should be appreciated that there are a number of different types of photolithographic apparatuses or devices. For example, photolithography apparatus 40, or an exposure apparatus, may be used as a scanning type photolithography system which exposes the pattern from reticle 68 onto wafer 64 with reticle 68 and wafer 64 moving substantially synchronously. In a scanning type lithographic device, reticle 68 is moved perpendicularly with respect to an optical axis of a lens assembly (projection optical system 46) or illumination system 42 by reticle stage 44. Wafer 64 is moved perpendicularly to the optical axis of projection optical system 46 by a wafer stage 52. Scanning of reticle 68 and wafer 64 generally occurs while reticle 68 and wafer 64 are moving substantially synchronously.

Alternatively, photolithography apparatus or exposure apparatus 40 may be a step-and-repeat type photolithography system that exposes reticle 68 while reticle 68 and wafer 64 are stationary, i.e., at a substantially constant velocity of approximately zero meters per second. In one step and repeat process, wafer 64 is in a substantially constant position relative to reticle 68 and projection optical system 46 during the exposure of an individual field. Subsequently, between consecutive exposure steps, wafer 64 is consecutively moved by wafer positioning stage 52 perpendicularly to the optical axis of projection optical system 46 and reticle 68 for exposure. Following this process, the images on reticle 68 may be sequentially exposed onto the fields of wafer 64 so that the next field of semiconductor wafer 64 is brought into position relative to illumination system 42, reticle 68, and projection optical system 46.

It should be understood that the use of photolithography apparatus or exposure apparatus 40, as described above, is not limited to being used in a photolithography system for semiconductor manufacturing. For example, photolithography apparatus 40 may be used as a part of a liquid crystal display (LCD) photolithography system that exposes an LCD device pattern onto a rectangular glass plate or a photolithography system for manufacturing a thin film magnetic head.

The illumination source of illumination system 42 may be g-line (436 nanometers (nm)), i-line (365 nm), a KrF excimer laser (248 nm), an ArF excimer laser (193 nm), and an F2-type laser (157 nm). Alternatively, illumination system 42 may also use charged particle beams such as x-ray and electron beams. For instance, in the case where an electron beam is used, thermionic emission type lanthanum hexaboride (LaB6) or tantalum (Ta) may be used as an electron gun. Furthermore, in the case where an electron beam is used, the structure may be such that either a mask is used or a pattern may be directly formed on a substrate without the use of a mask.

With respect to projection optical system 46, when far ultra-violet rays such as an excimer laser are used, glass materials such as quartz and fluorite that transmit far ultra-violet rays is preferably used. When either an F2-type laser or an x-ray is used, projection optical system 46 may be either catadioptric or refractive (a reticle may be of a corresponding reflective type), and when an electron beam is used, electron optics may comprise electron lenses and deflectors. As will be appreciated by those skilled in the art, the optical path for the electron beams is generally in a vacuum.

In addition, with an exposure device that employs vacuum ultra-violet (VUV) radiation of a wavelength that is approximately 200 nm or lower, use of a catadioptric type optical system may be considered. Examples of a catadioptric type of optical system include, but are not limited to, those described in Japan Patent Application Disclosure No. 8-171054 published in the Official gazette for Laid-Open Patent Applications and its counterpart U.S. Pat. No. 5,668,672, as well as in Japan Patent Application Disclosure No. 10-20195 and its counterpart U.S. Pat. No. 5,835,275, which are all incorporated herein by reference in their entireties. In these examples, the reflecting optical device may be a catadioptric optical system incorporating a beam splitter and a concave mirror. Japan Patent Application Disclosure (Hei) No. 8-334695 published in the Official gazette for Laid-Open Patent Applications and its counterpart U.S. Pat. No. 5,689,377, as well as Japan Patent Application Disclosure No. 10-3039 and its counterpart U.S. Pat. No. 5,892,117, which are all incorporated herein by reference in their entireties. These examples describe a reflecting-refracting type of optical system that incorporates a concave mirror, but without a beam splitter, and may also be suitable for use with the present invention.

The present invention may be utilized, in one embodiment, in an immersion type exposure apparatus if suitable measures are taken to accommodate a fluid. For example, PCT patent application WO 99/49504, which is incorporated herein by reference in its entirety, describes an exposure apparatus in which a liquid is supplied to a space between a substrate (wafer) and a projection lens system during an exposure process. Aspects of PCT patent application WO 99/49504 may be used to accommodate fluid relative to the present invention.

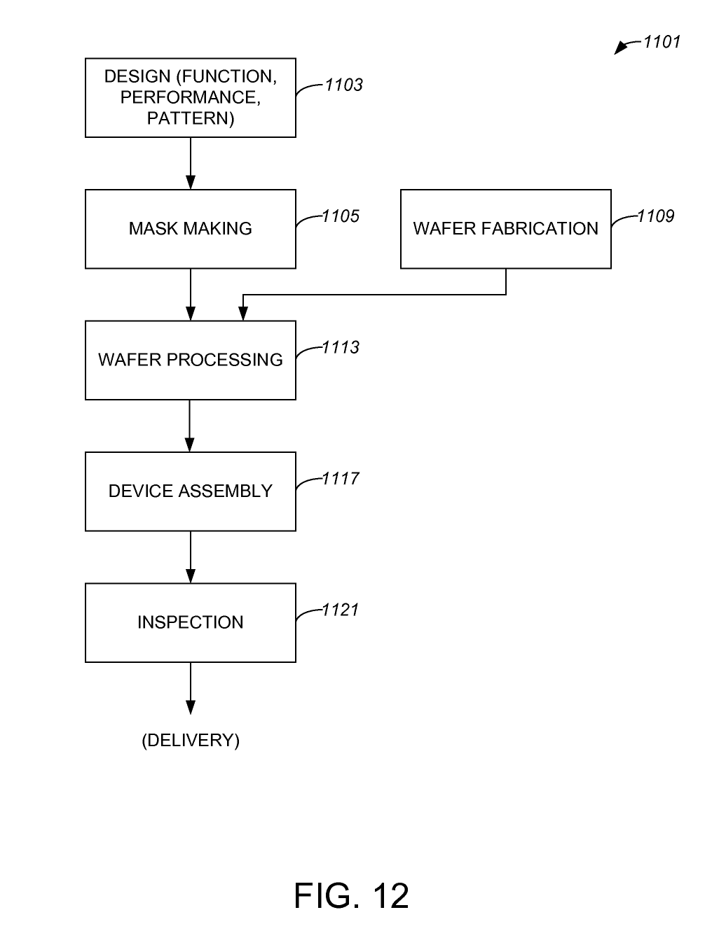

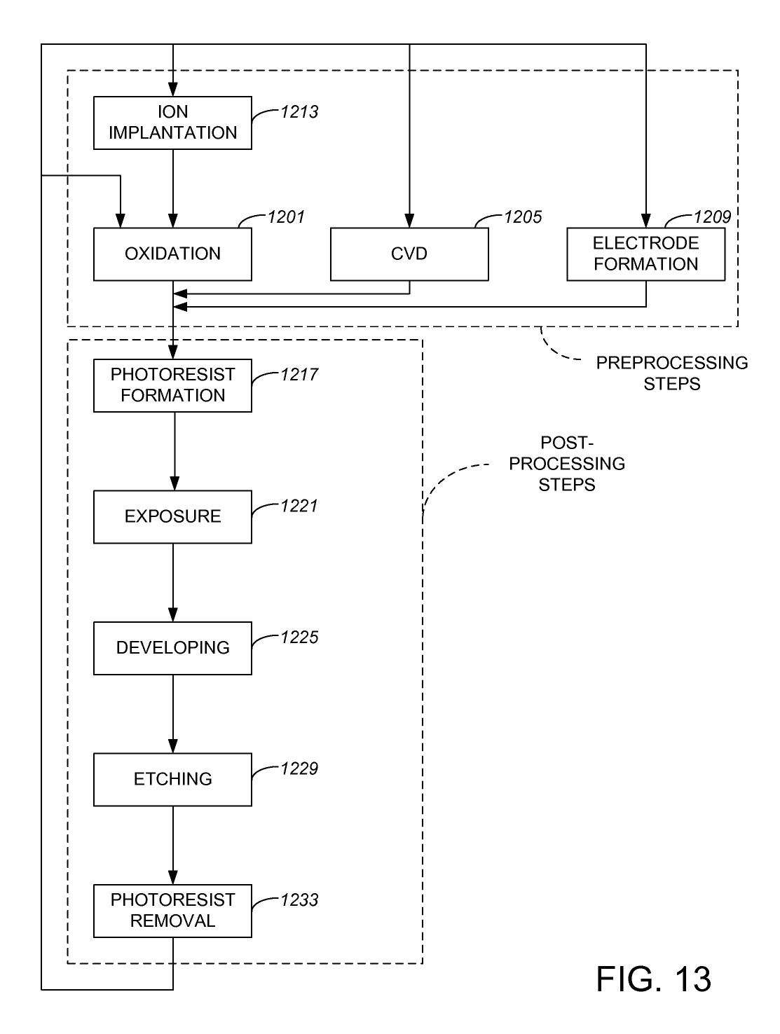

Further, semiconductor devices may be fabricated using systems described above, as will be discussed with reference to FIG. 13. FIG. 12 is a process flow diagram which illustrates the steps associated with fabricating a semiconductor device in accordance with an embodiment of the present invention. A process 1101 of fabricating a semiconductor device begins at step 1103 in which the function and performance characteristics of a semiconductor device are designed or otherwise determined. Next, in step 1105, a reticle or mask in which has a pattern is designed based upon the design of the semiconductor device. It should be appreciated that in a substantially parallel step 1109, a wafer is typically made from a silicon material. In step 1113, the mask pattern designed in step 1105 is exposed onto the wafer fabricated in step 1109. One process of exposing a mask pattern onto a wafer will be described below with respect to FIG. 13. In step 1117, the semiconductor device is assembled. The assembly of the semiconductor device generally includes, but is not limited to including, wafer dicing processes, bonding processes, and packaging processes. Finally, the completed device is inspected in step 1121. Upon successful completion of the inspection in step 1121, the completed device may be considered to be ready for delivery.

FIG. 13 is a process flow diagram which illustrates the steps associated with wafer processing, e.g., step 1113 of FIG. 12, in the case of fabricating semiconductor devices in accordance with an embodiment of the present invention. In step 1201, the surface of a wafer is oxidized. Then, in step 1205 which is a chemical vapor deposition (CVD) step in one embodiment, an insulation film may be formed on the wafer surface. Once the insulation film is formed, then in step 1209, electrodes are formed on the wafer by vapor deposition. Then, ions may be implanted in the wafer using substantially any suitable method in step 1213. As will be appreciated by those skilled in the art, steps 1201-1213 are generally considered to be preprocessing steps for wafers during wafer processing. Further, it should be understood that selections made in each step, e.g., the concentration of various chemicals to use in forming an insulation film in step 1205, may be made based upon processing requirements.

At each stage of wafer processing, when preprocessing steps have been completed, post-processing steps may be implemented. During post-processing, initially, in step 1217, photoresist is applied to a wafer. Then, in step 1221, an exposure device may be used to transfer the circuit pattern of a reticle to a wafer. Transferring the circuit pattern of the reticle of the wafer generally includes scanning a reticle scanning stage which may, in one embodiment, include a force damper to dampen vibrations.

After the circuit pattern on a reticle is transferred to a wafer, the exposed wafer is developed in step 1225. Once the exposed wafer is developed, parts other than residual photoresist, e.g., the exposed material surface, may be removed by etching in step 1229. Finally, in step 1233, any unnecessary photoresist that remains after etching may be removed. As will be appreciated by those skilled in the art, multiple circuit patterns may be formed through the repetition of the preprocessing and post-processing steps.

Although only a few embodiments of the present invention have been described, it should be understood that the present invention may be embodied in many other specific forms without departing from the spirit or the scope of the present invention. By way of example, a magnet arrangement may include any number of magnets, the number of coils in a coil array may vary widely, and the number of coils in a coil unit may vary widely. In addition, the sizes of magnets and coils may also vary.

Without smooth switching, a Z force or force generated in a Z direction by a YZ magnet quadrant may have a force discontinuity along an X direction substantially at every coil pitch. A smooth switching algorithm or scheme, as discussed above, may effectively remove such force discontinuities. A longer smoothing range may generally result in a smoother force.

Magnet quadrants of a magnet array have generally been described as having associated regions or ranges such that when the regions or ranges overlay a coil, the coil may be energized. It should be appreciated that the size of such regions or ranges may generally vary widely. By way of example, a region associated with a magnet quadrant may extend past the edges of the magnet quadrant such that a coil which is not directly under the magnet quadrant is still within the region associated with the magnet quadrant.

The many features of the embodiments of the present invention are apparent from the written description. Further, since numerous modifications and changes will readily occur to those skilled in the art, the present invention should not be limited to the exact construction and operation as illustrated and described. Hence, all suitable modifications and equivalents may be resorted to as falling within the spirit or the scope of the present invention.

What is claimed is:

1. A method for operating a planar motor, the planar motor including a magnet array and a coil array, the magnet array including at least a first magnet unit, the first magnet unit having an associated range, the coil array including at least a first coil and a second coil, the method comprising:
providing electrical current to the first coil when the first coil is within the range;
determining when the first magnet unit is in proximity to a switching location;
reducing the electrical current provided to the first coil when it is determined that the first magnet unit is in proximity to the switching location;
determining when the first magnet unit has reached the switching location after reducing the electrical current provided to the first coil; and
switching to providing the electrical current to a second coil when it is determined that the first magnet unit has reached the switching location, wherein switching to providing the electrical current to the second coil includes ceasing providing the electrical current to the first coil.

2. The method of claim 1 wherein reducing the electrical current to the first coil includes smoothly reducing the electrical current to the first coil, wherein smoothly reducing the electrical current to the first coil causes a force generated by the first coil to be smoothly reduced.

3. The method of claim 2 wherein smoothly reducing the electrical current to the first coil includes smoothly reducing the force generated by the first coil such that when the first magnet unit reaches the switching location, the first coil generates substantially no force.

4. The method of claim 2 wherein the switching to providing the electrical current to the second coil includes smoothly increasing the electrical current to the second coil, wherein smoothly increasing the electrical current to the second coil causes a force generated by the second coil to be smoothly increased.

5. The method of claim 4 wherein smoothly increasing the electrical current to the second coil causes the force generated by the second coil to be smoothly increased from substantially zero force.

6. The method of claim 1 wherein the providing the electrical current to the first coil includes providing the electrical current using an amplifier and providing the electrical current to the second coil includes providing the electrical current using the amplifier, the amplifier being configured to selectively provide the electrical current to the first coil and to the second coil.

7. The method of claim 6 wherein selectively providing the electrical current to the first coil and to the second coil includes operating an electrical switch to direct the electrical current to either the first coil or the second coil.

8. The method of claim 1 wherein the first coil is included in a first coil unit and the second coil is included in the second coil unit, and wherein providing the electrical current to the first coil includes providing the electrical current to all coils of the first coil unit and providing the electrical current to the second coil includes providing the electrical current to all coils of the second coil unit.

9. The method of claim 1 wherein the switching location is predetermined

10. The method of claim 1 wherein the electrical current to the second coil is reduced when the magnet unit is in proximity to the switching location.

11. The method of claim 10 wherein a reduction in electrical current is controlled by a current scaling factor, the current scaling factor being a smooth function of a distance between the magnet unit and the switching location.

12. The method of claim 11 wherein the smooth function is a continuous and differentiable function.

13. The method of claim 11 wherein the current scaling factor is determined by multiplying a plurality of current scaling sub-factors, and wherein each of the plurality of current scaling sub-factors is defined by a unit position in at least two substantially orthogonal directions.

14. The method of claim 1 wherein the stage is part of an exposure apparatus.

15. A wafer formed using the exposure apparatus of claim 14.

16. An apparatus, comprising:
a stage;
a motor configured to move the stage, the motor including at least a first coil and a second coil;
an amplifier configured to selectively provide electrical current to either the first coil or the second coil; and
a controller configured to control an overall force generated by the motor, wherein when moving the stage, the controller controls the overall force generated by the motor by:
causing the amplifier to provide the electrical current to the first coil; and
switching the amplifier, wherein switching the amplifier causes the amplifier to stop providing the electrical current to the first coil and to provide the electrical current to the second coil.

17. The apparatus of claim 16 wherein the controller is further configured to control the overall force generated by the motor by smoothly reducing a first force generated by the first coil before switching the amplifier.

18. The apparatus of claim 17 wherein the stage is configured to move to a predetermined switching location, wherein smoothly reducing the first force generated by the first coil occurs before the stage moves to a predetermined switching location.

19. The apparatus of claim 18 wherein smoothly reducing the first force generated by the first coil includes smoothly reducing the first force such that when the stage reaches the predetermined switching location, the first coil is generates substantially no force.

20. The apparatus of claim 19 wherein the stage is further configured to move past the predetermined switching location, and wherein the controller is still further configured to smoothly increase a second force generated by the second coil after switching the amplifier and after the stage moves past the predetermined switching location, whereby smoothly reducing the first force generated by the first coil and smoothly increasing the second force generated by the second coil reduces discontinuities in the force generated by the motor when moving the stage.

21. The apparatus of claim 18 wherein the motor includes a magnet unit, the magnet unit having an associated range, and wherein the controller causes the amplifier to provide the electrical current to the first coil when the first coil is within the associated range and wherein the predetermined switching location is a location at which the first coil is no longer within the associated range.

22. The apparatus of claim 21 wherein when the controller causes the amplifiers to provide the electrical current to the first coil, the second coil is not within the associated range, and wherein when the controller causes the amplifier to switch, the second coil is within the associated range.

23. The apparatus of claim 16 wherein the at least first coil is part of a first coil unit, the first coil unit including a third coil, and wherein switching the amplifier causes the amplifiers to stop providing the electrical current to the first coil unit.

24. The apparatus of claim 16 wherein the electrical current to the first coil is reduced when the stage is in proximity to a predetermined switching location.

25. The apparatus of claim 24 wherein the motor includes a magnet unit, and wherein a reduction in the electrical current is controlled by a current scaling factor, the current scaling factor being a smooth function of a distance between the magnet unit and the predetermined switching location.

26. The apparatus of claim 16 wherein the apparatus is an exposure apparatus.

28. A wafer formed using the exposure apparatus of claim 27.

29. An apparatus comprising:
a stage;
an actuator, the actuator configured to move the stage, the actuator including an array of coils and an array of magnets, the array of coils including at least a first coil and a second coil, the array of magnets including at least a first magnet sub-array, wherein the first magnet sub-array has an associated range;
an amplifier arrangement, the amplifier arrangement being coupled to the first coil and the second coil, wherein the amplifier arrangement is configured to selectively provide current to the first coil and to the second coil; and
a controller, the controller configured to control forces generated by the actuator to move the stage, the controller being configured to cause the amplifier arrangement to provide the current to the first coil and not to the second coil when the first coil is within the associated range, the controller still further being configured to cause the amplifier arrangement further to provide the current to the second coil and not to the first coil when the second coil is within the associated range, wherein the controller causes the amplifier arrangement to smoothly reduce a first force generated by the first coil before switching from providing the current to the first coil to providing the current to the second coil.

30. The apparatus of claim 29 wherein the controller further causes the amplifier arrangement to smoothly increase a second force generated by the second coil after switching from providing the current to the first coil to providing the current to the second coil.
